(19) United States
(12) Patent Application Publication
(10) Pub. No.: US 2019/0057931 A1
(43) Pub. Date: Feb. 21, 2019

(54) PACKAGE METHOD FOR GENERATING PACKAGE STRUCTURE WITH FAN-OUT INTERFACES

(71) Applicant: POWERTECH TECHNOLOGY INC., Hsinchu County (TW)

(72) Inventors: Hung-Hsin Hsu, HSINCHU COUNTY (TW); Nan-Chun Lin, HSINCHU COUNTY (TW); Shang-Yu Chang Chien, HSINCHU COUNTY (TW)

(21) Appl. No.: 15/680,176

(22) Filed: Aug. 17, 2017

(51) Int. Cl. H01L 23/498; H01L 21/78; H01L 23/00; H01L 21/56; H01L 21/48

(52) U.S. Cl. CPC H01L 23/49816; H01L 2924/381; H01L 21/78; H01L 24/29; H01L 24/46; H01L 24/06; H01L 24/96; H01L 21/561; H01L 21/4853; H01L 2224/04042; H01L 2224/02331; H01L 2224/02372; H01L 2224/02373; H01L 2224/02381; H01L 2224/02379; H01L 2224/03001; H01L 2924/181; H01L 23/49838

(57) ABSTRACT

A semiconductor package structure includes an encapsulant, a chip module, at least one auxiliary conduction block, and a redistribution layer. The chip module is encapsulated by the encapsulant. The chip module has a chip. Each of the at least one auxiliary conduction block has a plurality of auxiliary conductive bumps and a mold layer encapsulating the plurality of auxiliary conductive bumps. The redistribution layer is disposed on the encapsulant. The redistribution layer is used to electrically connect the chip of the chip module and the at least one auxiliary conduction block.

### BACKGROUND OF THE INVENTION

### 1. Field of the Invention

The present invention relates to a package method, and more particularly, a package method for generating a package with fan-out interfaces.

### 2. Description of the Prior Art

A fan-out chip may have a structure to act as an interface for connecting between a small pad pitch chip to a larger pitch substrate. The function of the structure may be similar to the function of a through-silicon via (TSV) interposer. The cost of manufacturing a fan-out chip should be lower than manufacturing a TSV interposer. When manufacturing a complicated chip with a higher pad count, the assembly packaging may be a challenge. If adopting a TSV interposer, the cost will be increased. If adopting a high density substrate, cost will also be increased.

FIG. 1 illustrates a fan-out package structure 100 according to prior art. The fan-out package structure 100 includes a chip 110c, a substrate 120 and a mold layer 110m. The chip 110c has a plurality of interfaces 11101-11104. The substrate 120 has a first side 120a, a second side 120b, a set of first interfaces 11201-11204 formed on the first side 120a and a set of second interfaces 11201′-11204′ formed on the second side 120b. The first interfaces 11201-11204 are connected to the interfaces 11101-11104 of the chip 110c, and corresponding to the second interfaces 11201′-11204′.

The pitch L between two adjacent second interfaces of the second interfaces 11201′-11204′ is larger than the pitch between two adjacent interfaces of the interfaces 1101-1104. Hence, for example, when the chip 110c may be a fan-out chip with a high ball count, the fan-out structure increases the pitch thereby improving the yield. A solution with a competitive cost is yet to be found for a package structure embedded with two or more chips.

### SUMMARY OF THE INVENTION

An embodiment of the present invention provides a semiconductor package structure including an encapsulant, a chip module, at least one auxiliary conduction block, and a redistribution layer. The chip module is encapsulated by the encapsulant. The chip module has a chip. Each of the at least one auxiliary conduction block has a plurality of auxiliary conductive bumps and a mold layer encapsulating the plurality of auxiliary conductive bumps. The redistribution layer is disposed on the encapsulant. The redistribution layer is used to electrically connect the chip of the chip module and the at least one auxiliary conduction block.

An embodiment of the present invention provides a method of forming a semiconductor package. The method includes providing a tooling plate; disposing a chip module on the tooling plate, the chip module having a chip; disposing at least one auxiliary conduction block on the tooling plate, each of the at least one auxiliary conduction block having a plurality of auxiliary conductive bumps and a mold layer encapsulating the plurality of auxiliary conductive bumps; forming an encapsulant on the tooling plate to encapsulate the chip module and the at least one auxiliary conduction block; forming a redistribution layer on the tooling plate, the redistribution layer being configured to electrically connect the chip of the chip module and the at least one auxiliary conduction block; and removing the tooling plate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a fan-out package structure according to prior art.

FIGS. 2-13 illustrate a process of generating a plurality of chip modules according to an embodiment of the present invention.

FIGS. 14-21 illustrate a process of generating a plurality of auxiliary conduction blocks according to an embodiment of the present invention.

FIG. 22-FIG. 27 illustrate a process of generating a plurality of semiconductor packages according to an embodiment of the present invention.

FIG. 28 illustrates a package structure according to an embodiment of the present invention.

FIG. 29 illustrates a package structure according to an embodiment of the present invention.

FIG. 30 illustrates a package structure according to an embodiment of the present invention.

FIGS. 31-37 illustrate a process of generating a plurality of semiconductor packages according to an embodiment of the present invention.

FIG. 38 illustrates a package structure according to an embodiment of the present invention.

FIG. 39 illustrates a package structure according to another embodiment of the present invention.

FIG. 40 illustrates a package structure according to an embodiment of the present invention.

FIGS. 41-42 illustrate two top views of the layout of two chips and their corresponding auxiliary conduction blocks according to embodiments of the present invention.

FIG. 43 illustrates a process of generating a package structure according to an embodiment of the present invention.

FIG. 44 illustrates a top view of a structure formed after performing the process of FIG. 43

### DETAILED DESCRIPTION

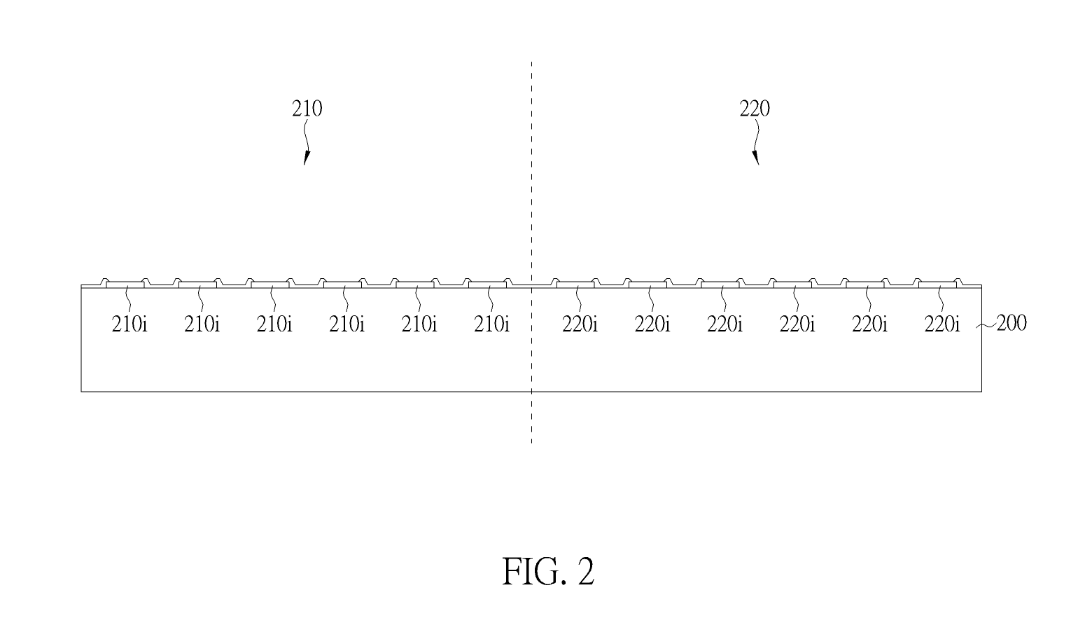

FIGS. 2-13 illustrate a process of generating a plurality of chip modules according to an embodiment of the present invention.

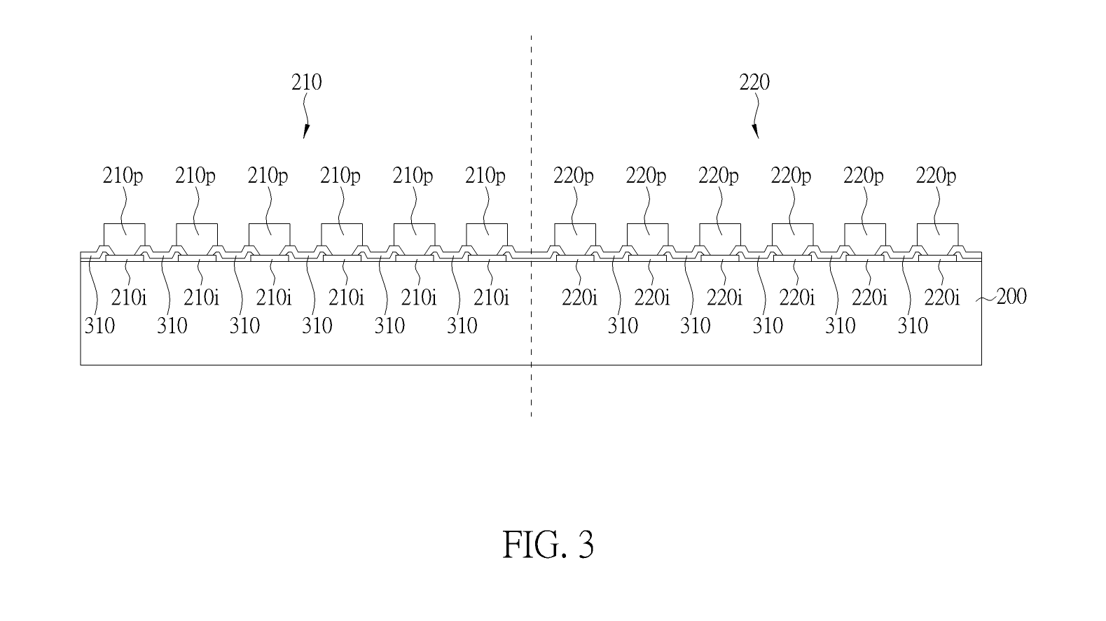

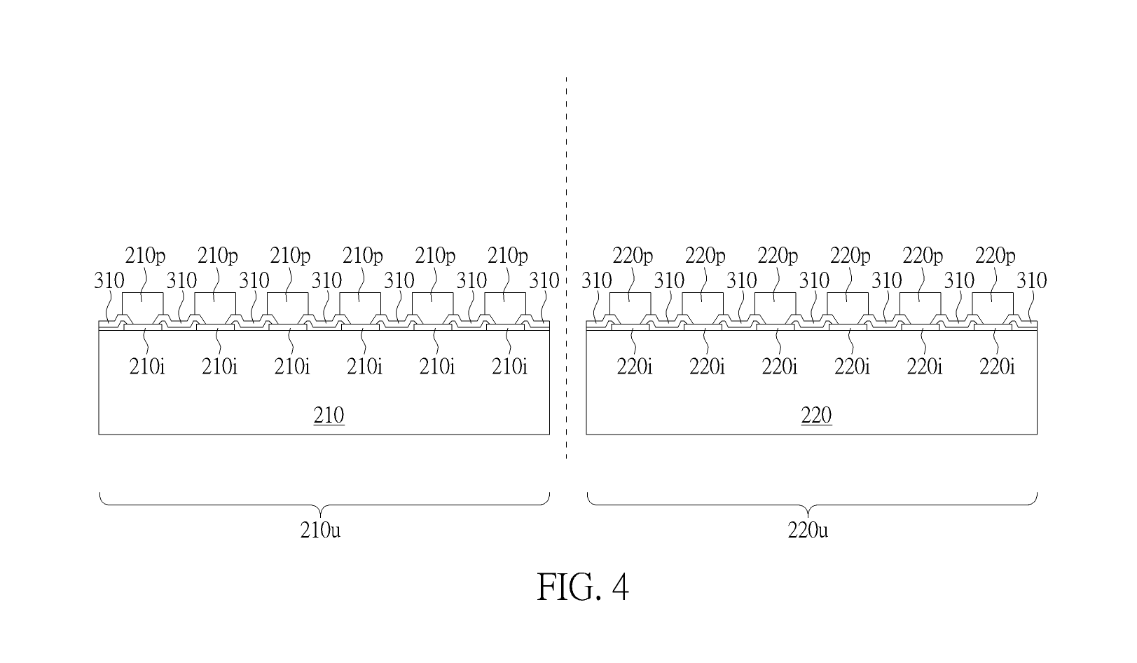

FIG. 2 illustrates a first chip 210 and a second chip 220 formed on a wafer 200. The first chip 210 comprises first conductive interfaces 210i. The second chip 220 comprises second conductive interfaces 220i. As shown in FIG. 3, a dielectric layer 310 may be formed on the first conductive interfaces 210i of the first chip 210 and the second conductive interfaces 220i of the second chip 220. The dielectric layer 310 may be patterned to expose the first conductive interfaces 210i and the second conductive interfaces 220i. When patterning the dielectric layer 310, suitable light may be applied to an unwanted portion of the dielectric layer 310 to remove the unwanted portion if the dielectric layer 310 is positive-working photosensitive. In another example, suitable light may be applied to a needed portion of the dielectric layer 310 to keep the needed portion if the dielectric layer 310 is negative-working photosensitive, and an unwanted portion that is not under exposure may be removed. In another example, a photoresist may be used to remove an unwanted portion if the dielectric layer 310 is non-photosensitive. A developing operation and a curing operation may be performed to clean the unwanted portion of the dielectric layer 310 and fix the remaining portion of the dielectric layer 310. According to an embodiment of the present invention, the dielectric layer 310 may be of polyimide (PI). A plurality of first conductive pillar bumps 210p may be formed on the corresponding first conductive interfaces 210i. A plurality of second conductive pillar bumps 220p may be formed on the corresponding second conductive interfaces 220i. As shown in FIG. 4, the wafer 200 may be divided to separate the first chip 210 from the second chip 220 so as to obtain a first chip unit 210u and a second chip unit 220u. The first chip unit 210u may include the first chip 210 and the first conductive pillar bumps 210p. The second chip unit 220u may include the second chip 220 and the second conductive pillar bumps 220p. In FIGS. 2-4, the flow of obtaining the two chip units 210u-220u is merely an example. More than two chip units may be generated by using a similar method. For example, when a wafer bears N chips where N is a positive integer larger than 1, N chip units may be generated.

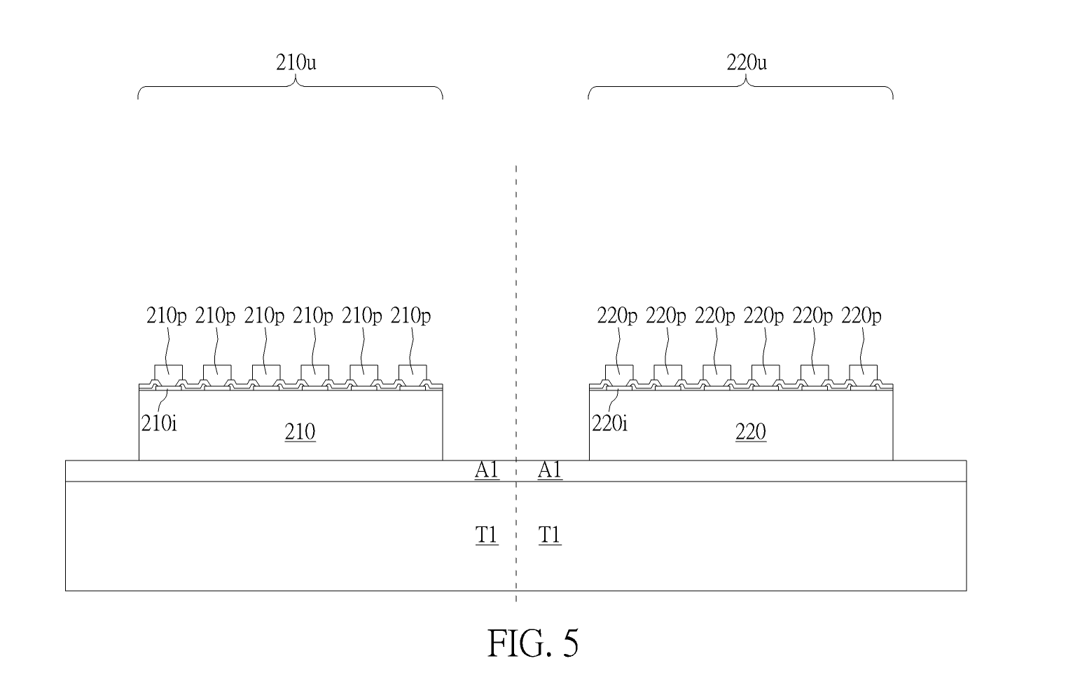

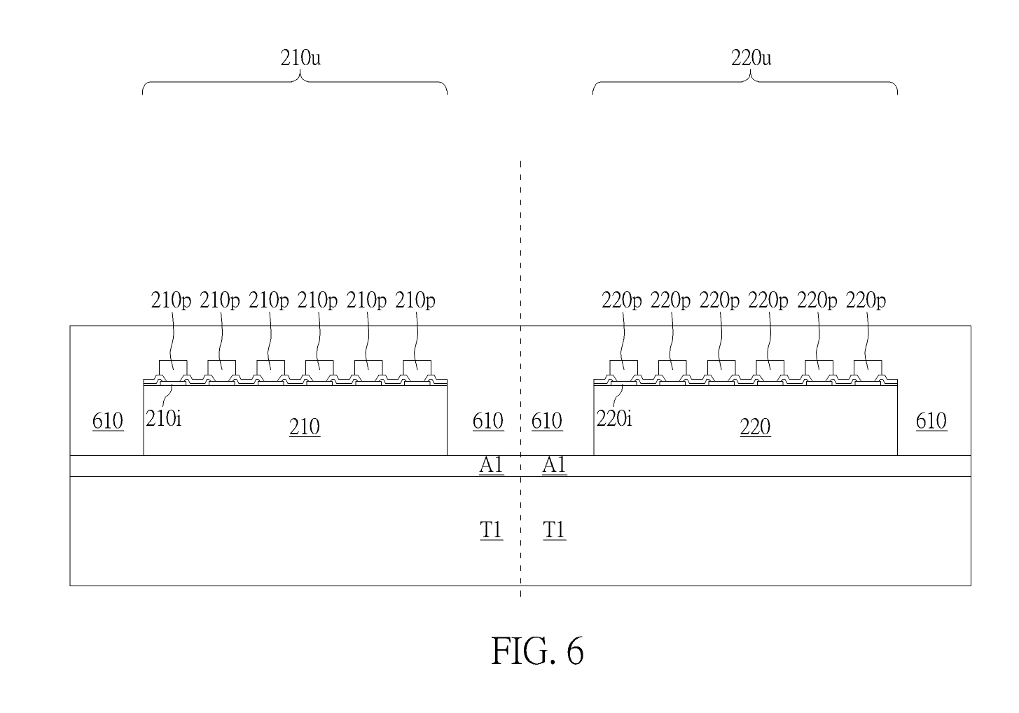

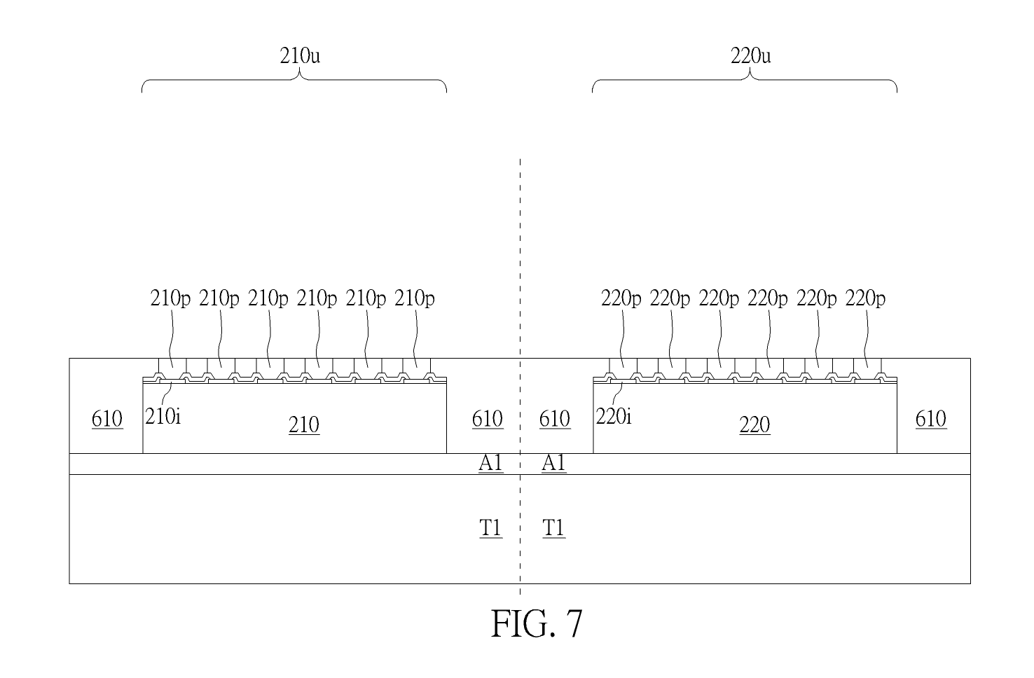

As shown in FIG. 5, a first adhesive layer A1 may be disposed on a first tooling plate T1, and the chip units 210u-220u may be disposed on the adhesive layer A1. The adhesive layer A1 may be formed by filling an adhesive material, or by disposing an attach film. The chip units 210u-220u in FIG. 5 are used as an example, according to an embodiment of the present invention, more chip units may be disposed on the adhesive layer A1 for performing the following operations. In FIG. 6, a mold material may be filled to form a first mold layer 610. The first mold layer 610 may encapsulate the chip units 210u-220u. As shown in FIG. 7, the first mold layer 610 may be thinned to expose the first conductive pillar bumps 210p and the second conductive pillar bumps 220p. The first mold layer 610 may be thinned by grinding.

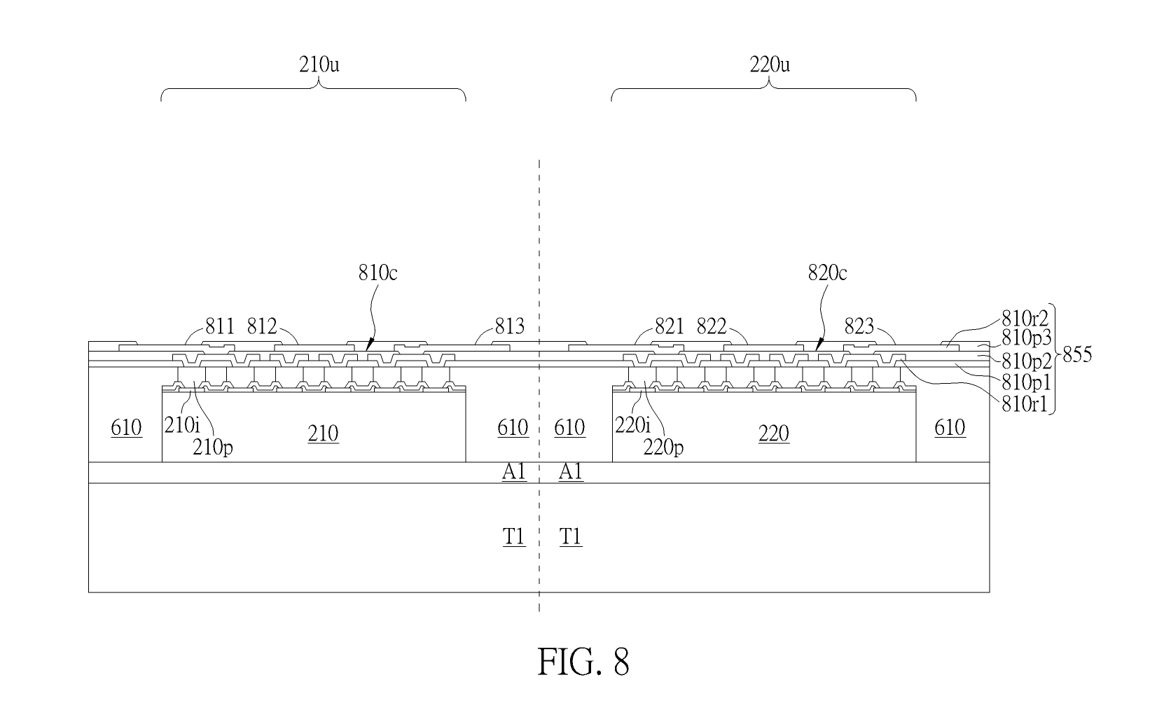

As shown in FIG. 8, a redistribution layer 855 may be formed on the thinned first mold layer 610. The redistribution layer 855 may include circuitries 810c-820c. The circuitry 810c may be electrically connected to the first conductive pillar bumps 210p, and the circuitry 820c may be electrically connected to the second conductive pillar bumps 220p.

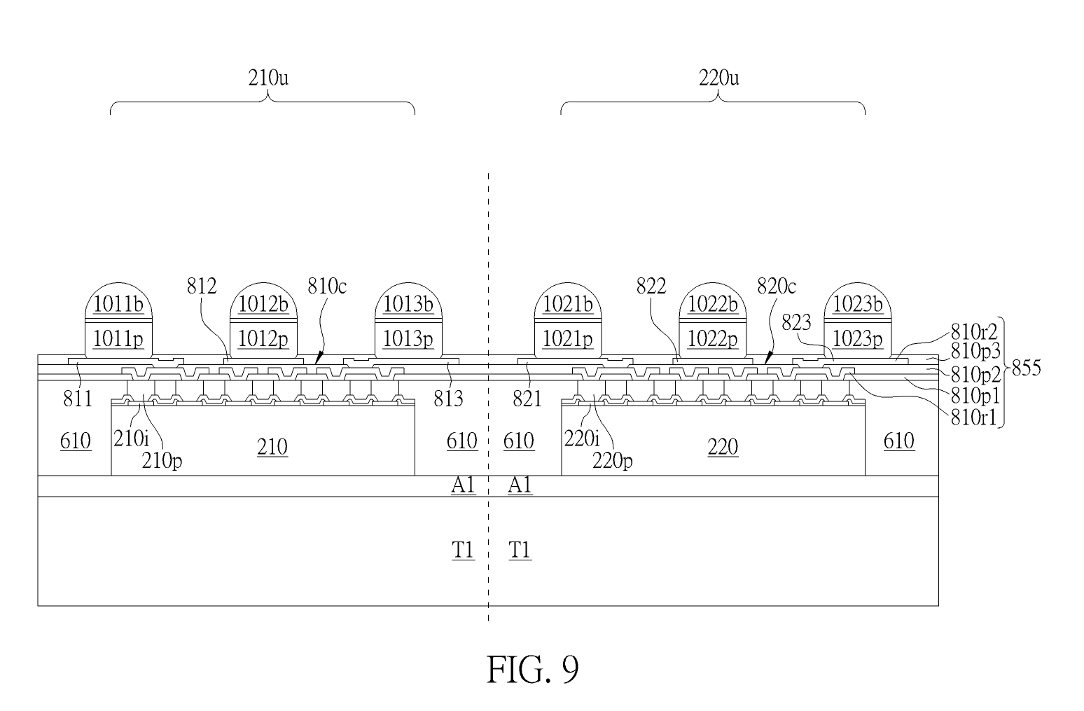

As shown in FIG. 9, a set of intermediary conductive pillars 1011p-1013p may be disposed on the corresponding fan-out interfaces 811-813. A set of conductive bumps 1011b-1013b may be disposed on the set of intermediary conductive pillars 1011p-1013p correspondingly. A set of intermediary conductive pillars 1021p-1023p may be formed on the corresponding fan-out interfaces 821-823. A set of conductive bumps 1021b-1023b may be formed on the set of intermediary conductive pillars 1021p-1023p correspondingly.

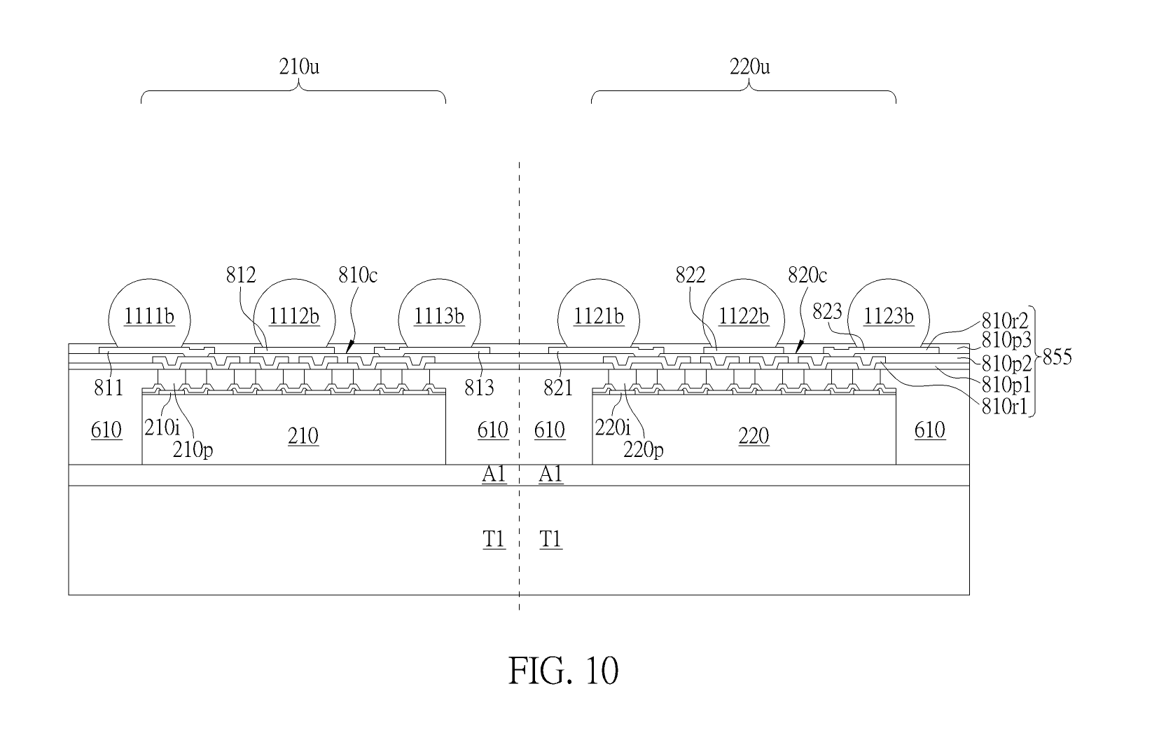

According to another embodiment of present invention, conductive bumps may be formed directly on the fan-out interfaces. As shown in FIG. 10, a set of conductive bumps 1111b-1113b may be formed on the corresponding fan-out interfaces 811-813. A set of conductive bumps 1121b-1123b may be formed on the corresponding fan-out interfaces 821-823.

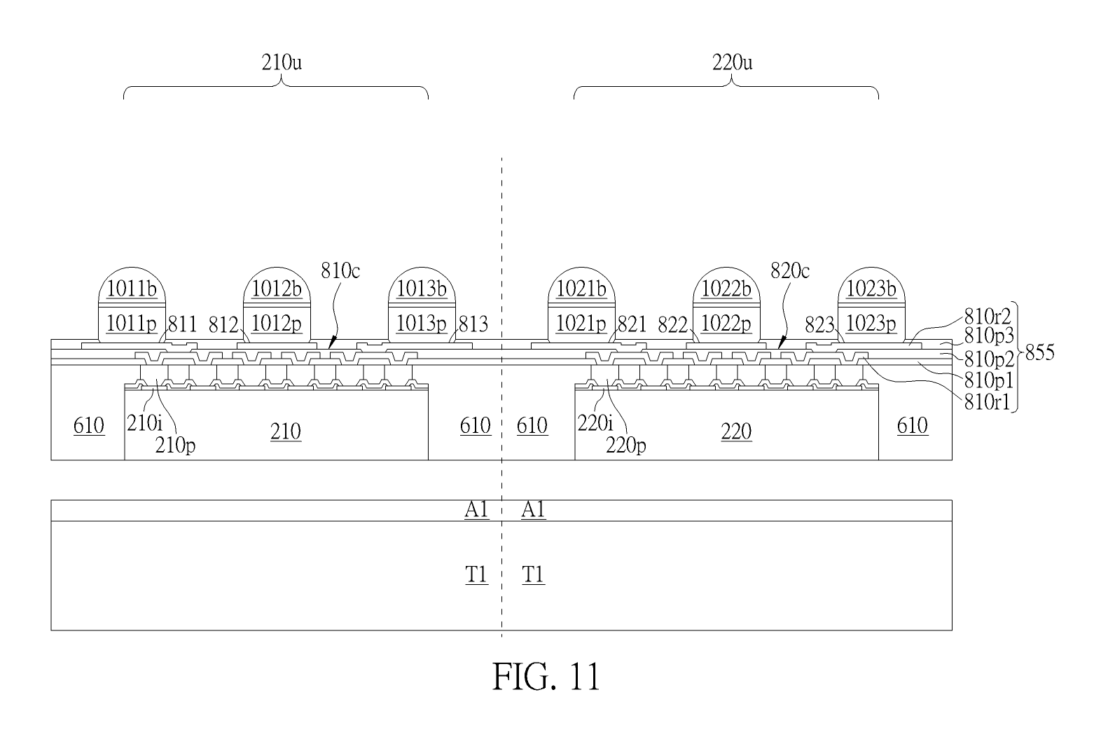

Take the embodiment of FIG. 9 as an example. As shown in FIG. 11, after forming the redistribution layer 855, disposing the intermediary conductive pillars 1011p-1013p and 1021p-1023p, and bonding the conductive bumps 1011b-1013b and 1021b-1023b, the tooling plate Tl may be removed. The adhesive layer A1 may be exposed to specific light, heat, and/or other means.

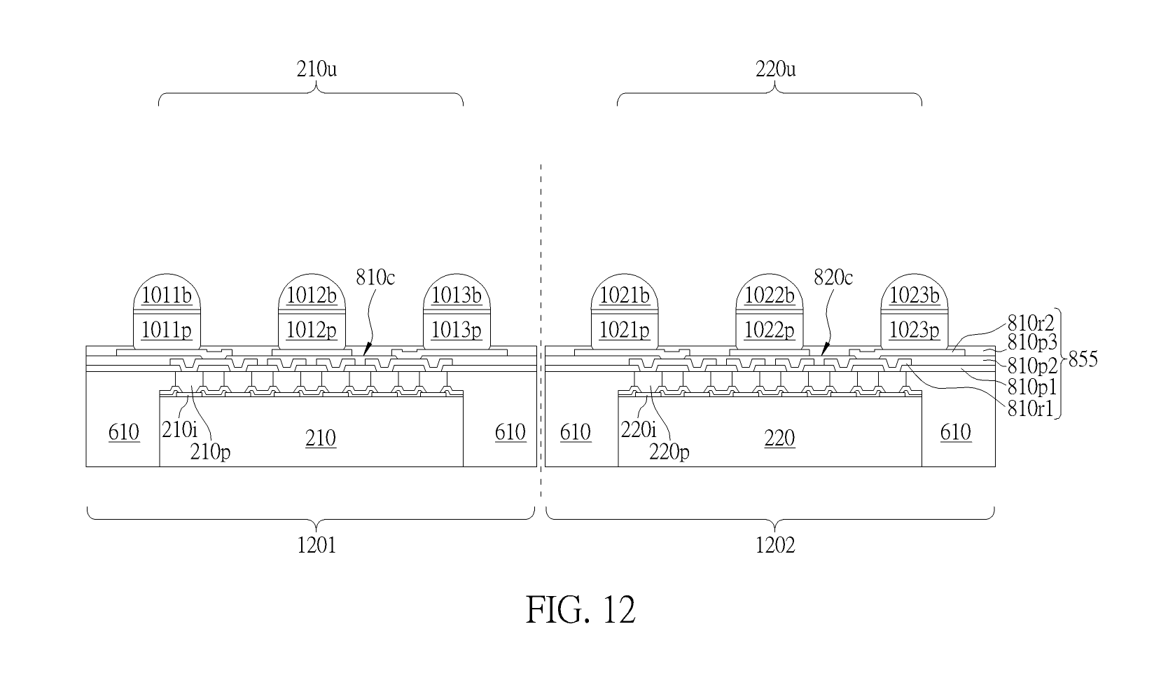

As shown in FIG. 12, the first mold layer 610 and redistribution layer 855 may be divided to separate the chip 210 from the chip 220 and form a fan-out chip module 1201 and a fan-out chip module 1202. The first mold layer 610 and the redistribution layer 855 may be divided by sawing, laser cutting or other suitable cutting process.

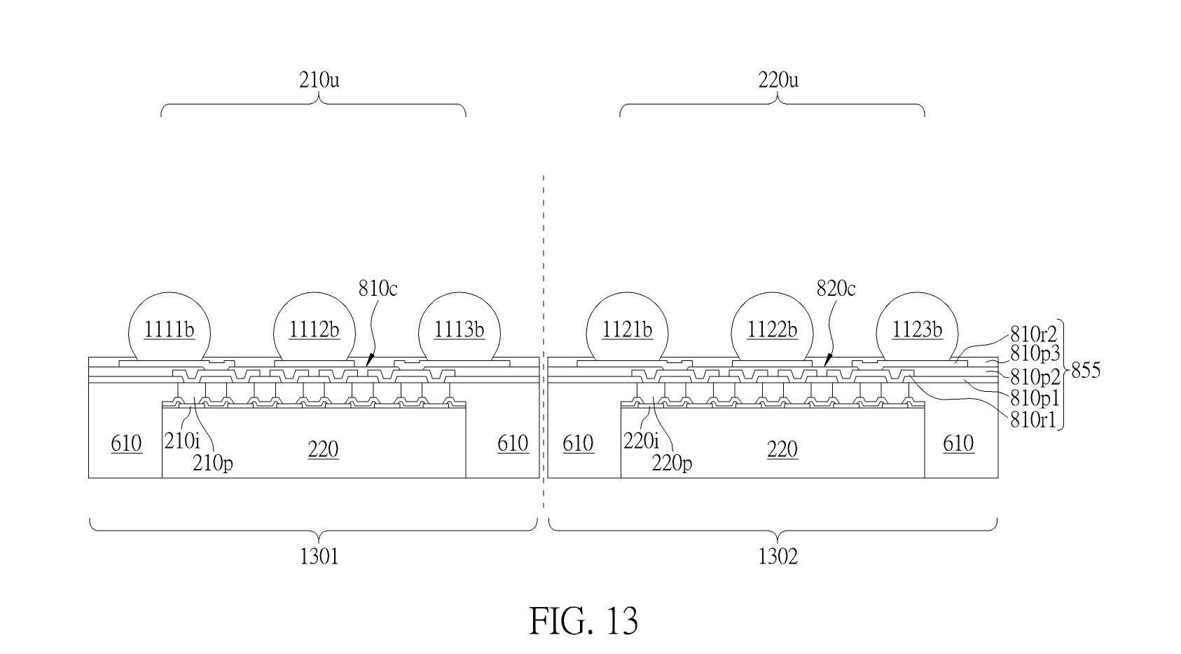

As shown in FIG. 13, the first mold layer 610 and redistribution layer 855 may be divided to separate the chip 210 from the chip 220 and form a fan-out chip module 1301 and a fan-out chip module 1302. Similarly, the first mold layer 610 and the redistribution layer 855 may be divided by sawing, laser cutting or other suitable cutting process in the process of FIG. 13.

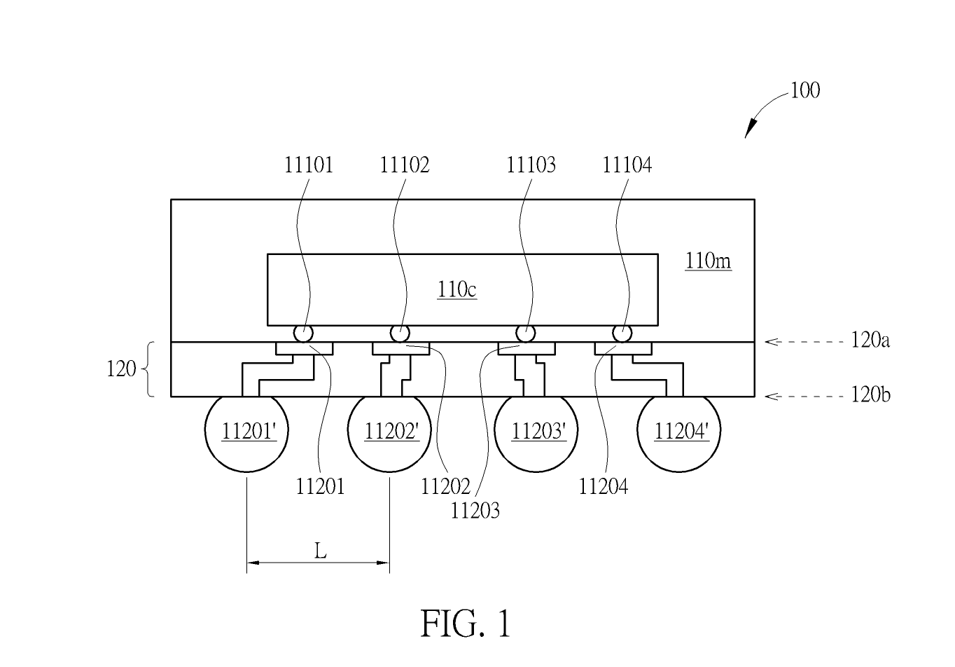

By performing the process of FIGS. 1-10 and 12, or the process of FIGS. 1-9, 11 and 13, a plurality of chip modules may be generated. Each chip module may include at least one corresponding chip and a fan-out structure. More chips may be included in a chip module according to an embodiment.

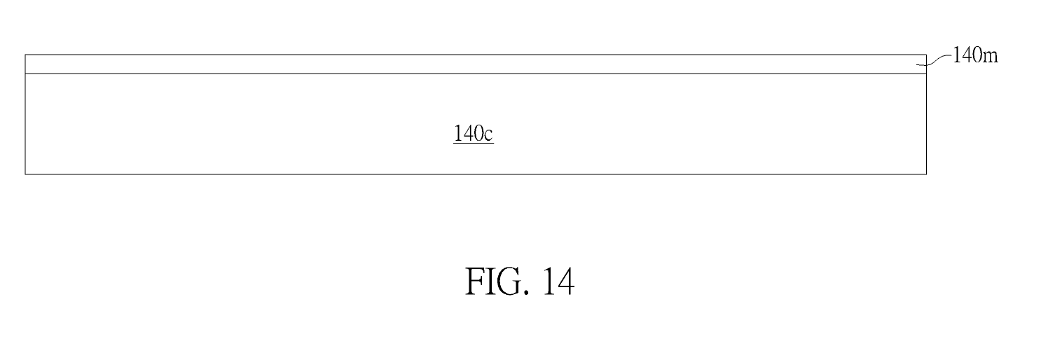

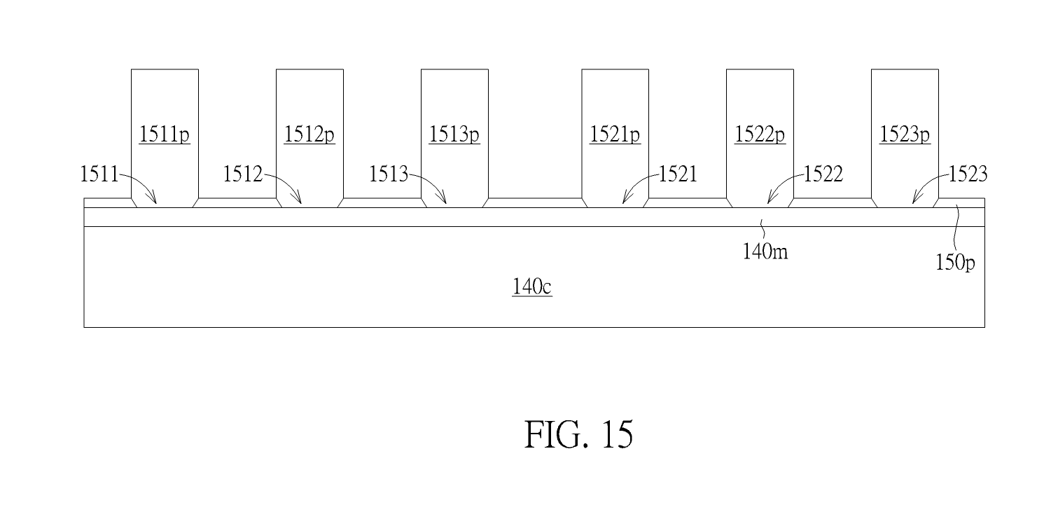

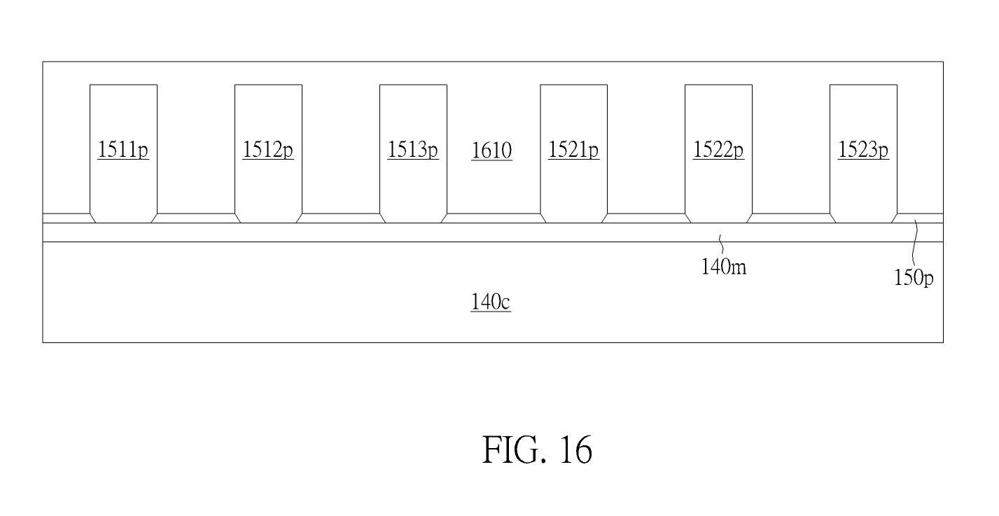

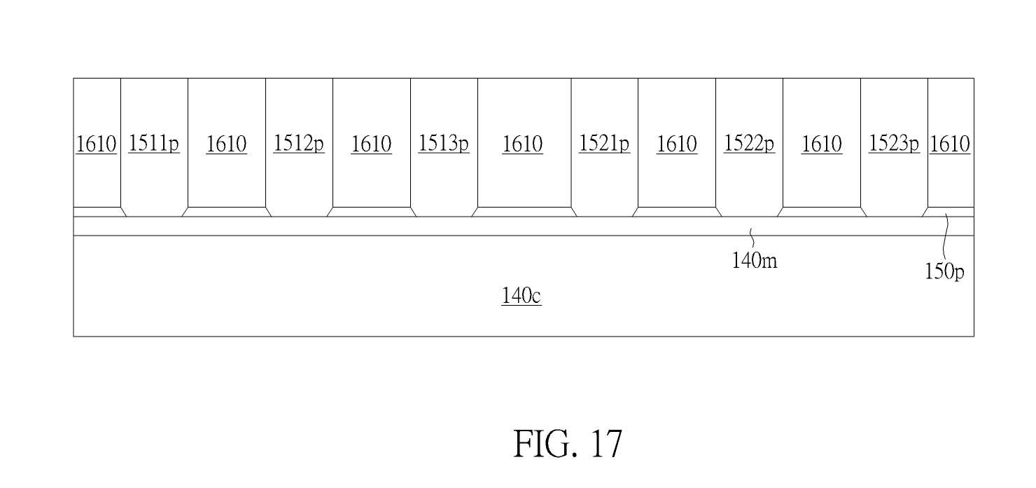

FIGS. 14-21 illustrate a process of generating a plurality of auxiliary conduction blocks according to an embodiment of the present invention. As shown in FIG. 14, a conductive layer 140m may be formed on a carrier 140c. The conductive layer 140m may be formed through copper foil lamination, electroplating (e-plating), or physical vapor deposition (PVD). The carrier 140c may be made of glass, silicon, ceramic or another suitable material. As shown in FIG. 15, a dielectric layer 150p may be formed on the conductive layer 140m. The dielectric layer 150p may be patterned by removing an unwanted portion of the dielectric layer 150p. In FIG. 15, openings 1511-1513 and 1521-1523 may be generated by removing a portion of the dielectric layer 150p. Each of the openings 1511-1513 and 1521-1523 may expose a portion of the conductive layer 140m. A plurality of auxiliary conductive pillars 1511p-1513p and 1521p-1523p may be formed on the conductive layer 140m via the openings 1511-1513 and 1521-1523 correspondingly. As shown in FIG. 16, a mold material may be filled to form a second mold layer 1610 to encapsulate the auxiliary conductive pillars 1511p-1513p and 1521p-1523p. As shown in FIG. 17, the second mold layer 1610 may be thinned to expose the auxiliary conductive pillars 1511p-1513p and 1521p-1523p.

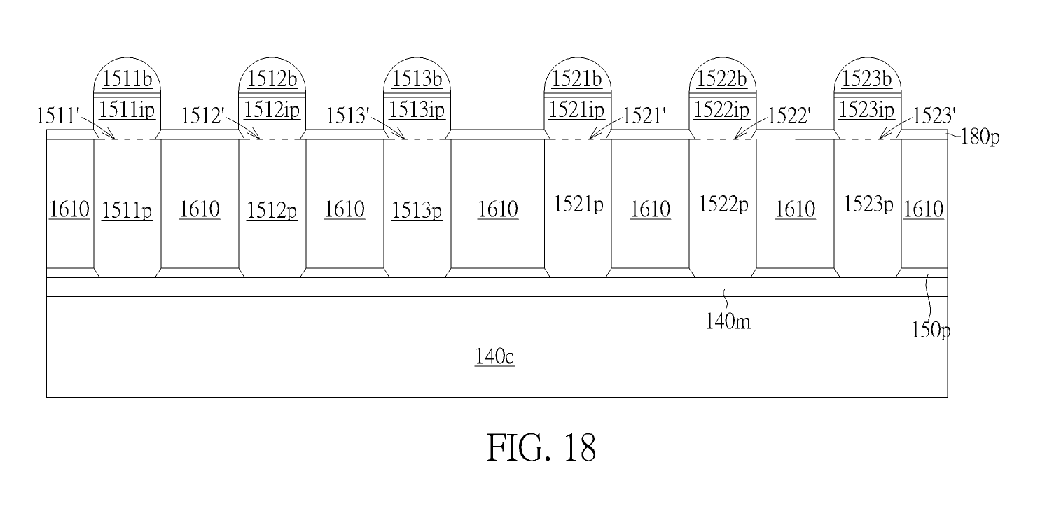

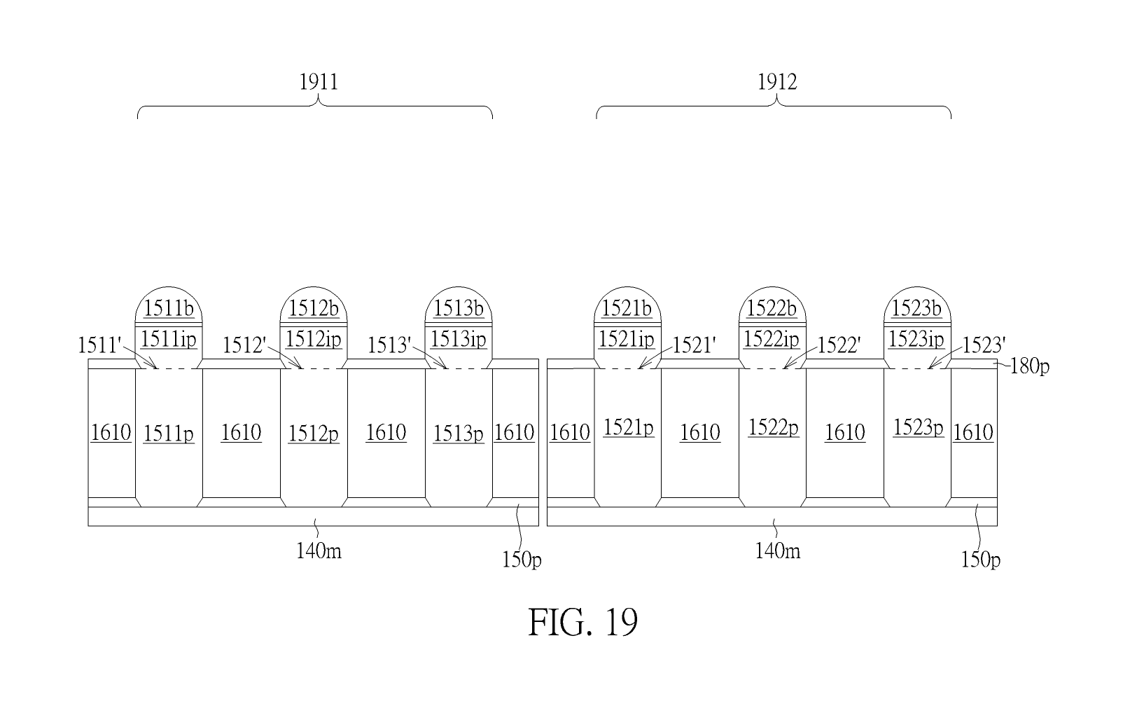

After exposing the auxiliary conductive pillars 1511p-1513p and 1521p-1523p, a process of FIGS. 18-19 may be performed according to an embodiment of the present invention.

As shown in FIG. 18, a plurality of auxiliary intermediary pillars 1511ip-1513ip and 1521ip-1523ip may be disposed on the auxiliary conductive pillars 1511p-1513p and 1521p-1523p correspondingly. A dielectric layer 180p may be formed on the thinned second mold layer 1610 and the exposed auxiliary conductive pillars 1511p-1513p and 1521p-1523p. A plurality of openings 1511′-1513′ and 1521′-1523′ corresponding to the auxiliary conductive pillars 1511p-1513p and 1521p-1523p may be formed. The auxiliary intermediary pillars 1511ip-1513ip and 1521ip-1523ip may be formed on the openings 1511′-1513′ and 1521′-1523′ correspondingly. A plurality of auxiliary conductive bumps 1511b-1513b and 1521b-1523b may be correspondingly disposed on the auxiliary intermediary pillars 1511ip-1513ip and 1521ip-1523ip. As shown in FIG. 19, the carrier 140c may be removed by a de-bonding process, and the second mold layer 1610, the conductive layer 140m, and the dielectric layers 150p and 180p may be cut by sawing or other cutting processes to form a plurality of auxiliary conduction blocks 1911-1912. In FIG. 19, the number of the auxiliary conduction blocks 1911-1912 is two, but the number is merely used as an example rather than being used to limit the scope of the present invention. More auxiliary conduction blocks may be formed.

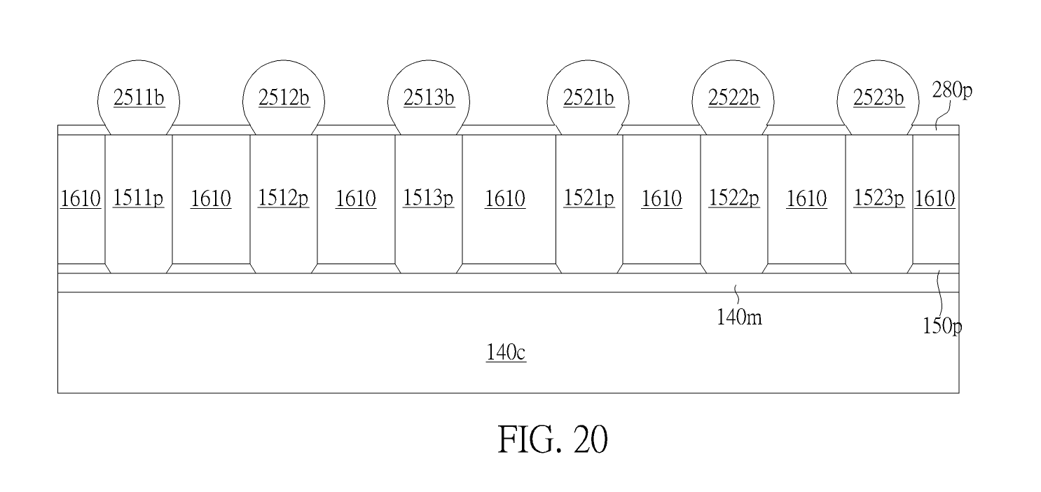

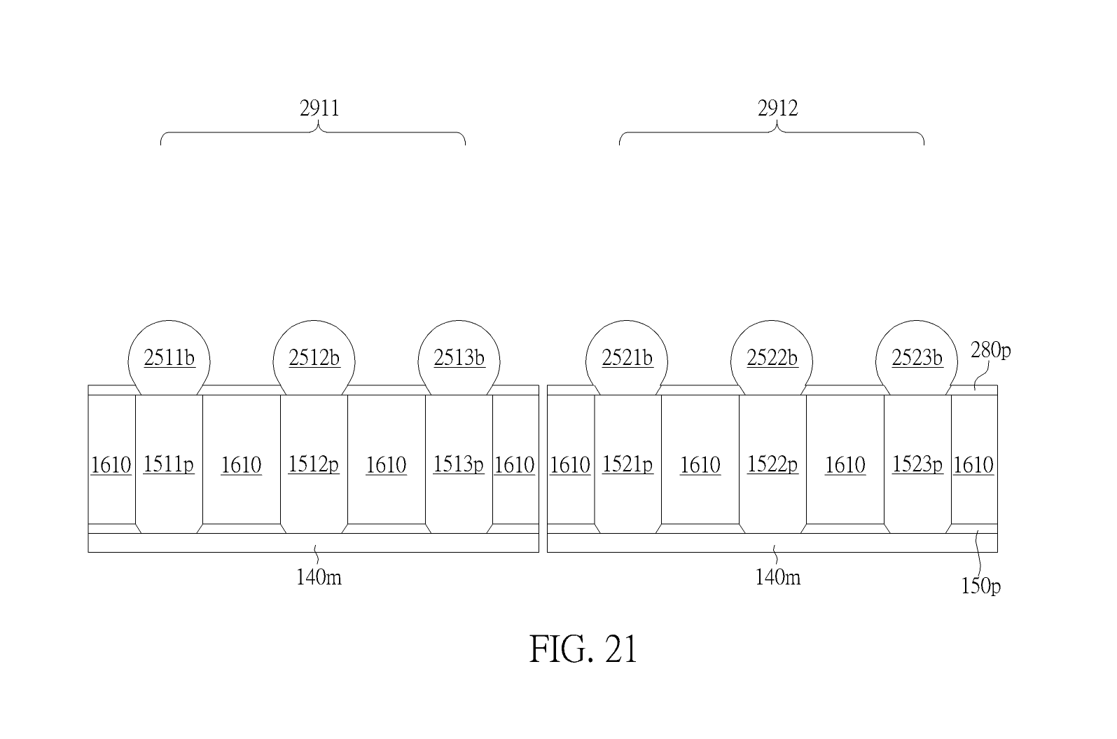

After exposing the auxiliary conductive pillars 1511p-1513p and 1521p-1523p as shown in FIG. 17, a process shown in FIGS. 20-21 may be performed according to another embodiment of the present invention. In FIG. 20, similar to FIG. 18, a dielectric layer 280p may be formed on the second mold layer 1610 and the auxiliary conductive pillars 1511p-1513p and 1521p-1523p. The dielectric layer 280p may be patterned to generate openings corresponding to the auxiliary conductive pillars 1511p-1513p and 1521p-1523p. Moreover a plurality of auxiliary conductive bumps 2511b-2513b and 2521b-2523b may be correspondingly disposed on the auxiliary conductive pillars 1511p-1513p and 1521p-1523p. As shown in FIG. 21, after disposing the auxiliary conductive bumps 2511b-2513b and 2521b-2523b, the carrier 140c may be removed, and the second mold layer 1610, the dielectric layers 280p and 150p, and the conductive layer 140m may be cut to form a plurality of auxiliary conduction blocks 2911-2912.

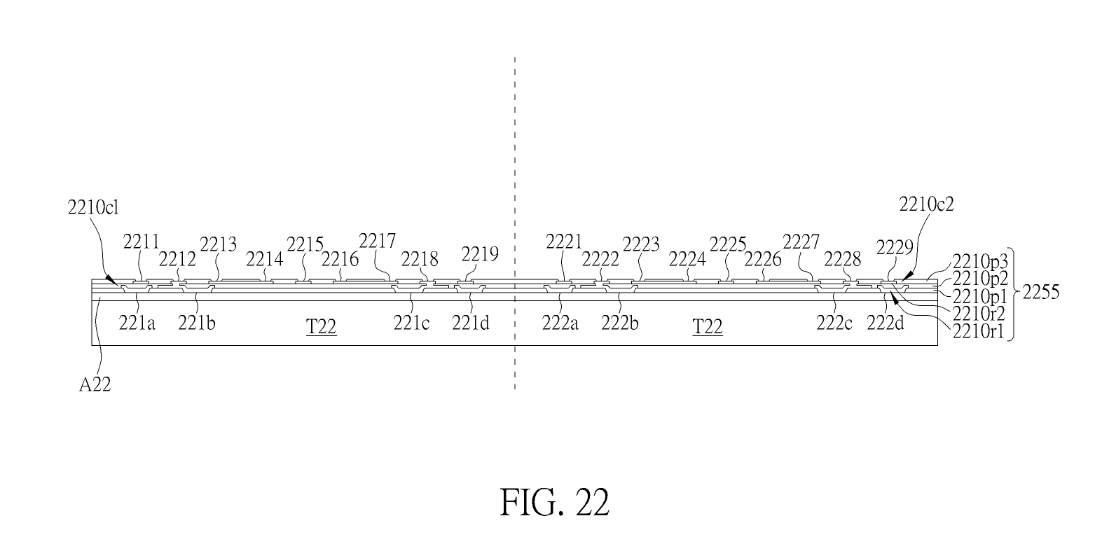

FIG. 22-FIG. 27 illustrate a process of generating a plurality of semiconductor package 2710-2720 according to an embodiment of the present invention. As shown in FIG. 22, an release layer A22 may be disposed on a tooling plate T22. A redistribution layer 2255 may be formed on the release layer A22. The redistribution layer 2255 may include two circuitries 2210c1-2210c2. The circuitry 2210c1 may include a plurality of conductive interfaces 2211-2219 and 221a-221d. The conductive interfaces 2211-2219 may be formed on the first side of the redistribution layer 2255, and the conductive interfaces 221a-221d may be formed on the second side of the redistribution layer 2255. The circuitry 2210c2 may include a plurality of conductive interfaces 2221-2229 and 222a-222d. The conductive interfaces 2221-2229 may be formed on the first side of the redistribution layer 2255, and the conductive interfaces 221a-221d may be formed on the second side of the redistribution layer 2255. The circuitries 2210c1-2210c2 and the conductive interfaces 2211-2219, 221a-221d, 2221-2229 and 222a-222d may be formed by forming and patterning the dielectric layers 2210p1-2210p3 and conductive layers 2210r1-2210r2 . The numbers of the circuitries and the conductive interfaces shown in FIG. 22 are merely used as an example rather than being used to limit the scope of the present invention.

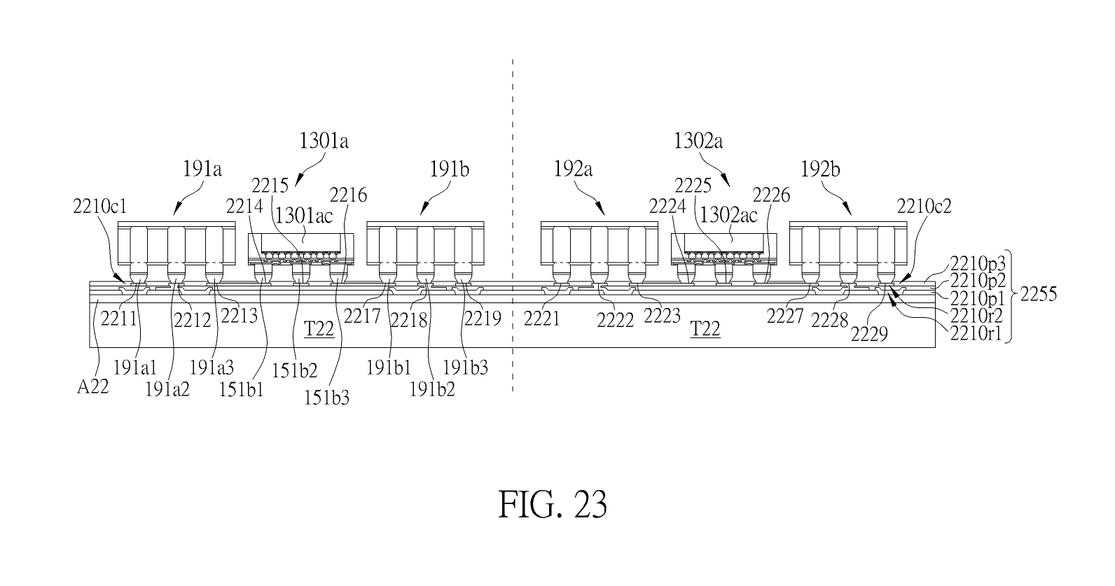

As shown in FIG. 23, a chip module 1301a may be disposed on the conductive interfaces 2214-2216 by correspondingly coupling the conductive bumps 151b1-151b3 to the conductive interfaces 2214-2216. At least two auxiliary conduction blocks 191a-191b may be disposed on the conductive interfaces 2211-2213 and 2217-2219. The auxiliary conductive bumps 191a1-191a3 of the auxiliary conduction block 191a and auxiliary conductive bumps 191b1-191b3 of the auxiliary conduction blocks 191b may be correspondingly coupled to the conductive interfaces 2211-2213 and conductive interfaces 2217-2219. Similarly, a chip module 1302a may be disposed on the conductive interfaces 2224-2226. An auxiliary conduction block 192a may be disposed on the conductive interfaces 2221-2223. An auxiliary conduction blocks 192b may be disposed on the conductive interfaces 2227-2229. The chip modules 1301a-1302a may be generated according to the process shown in FIGS. 2-10 and 12. The auxiliary conduction blocks 191a-191b and 192a-192b may be generated according to the process shown in FIGS. 14-19.

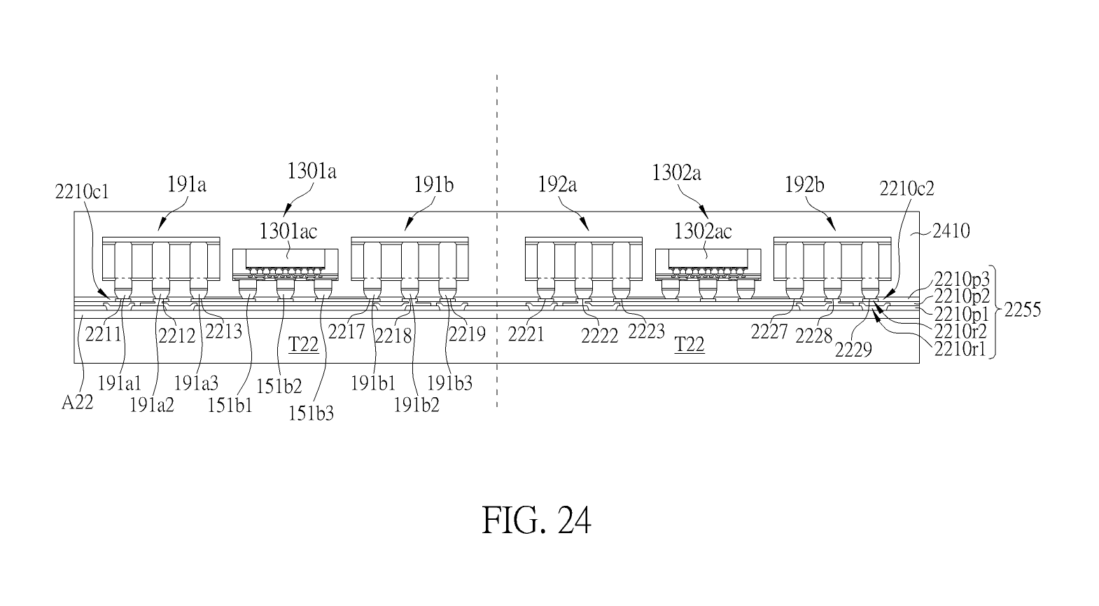

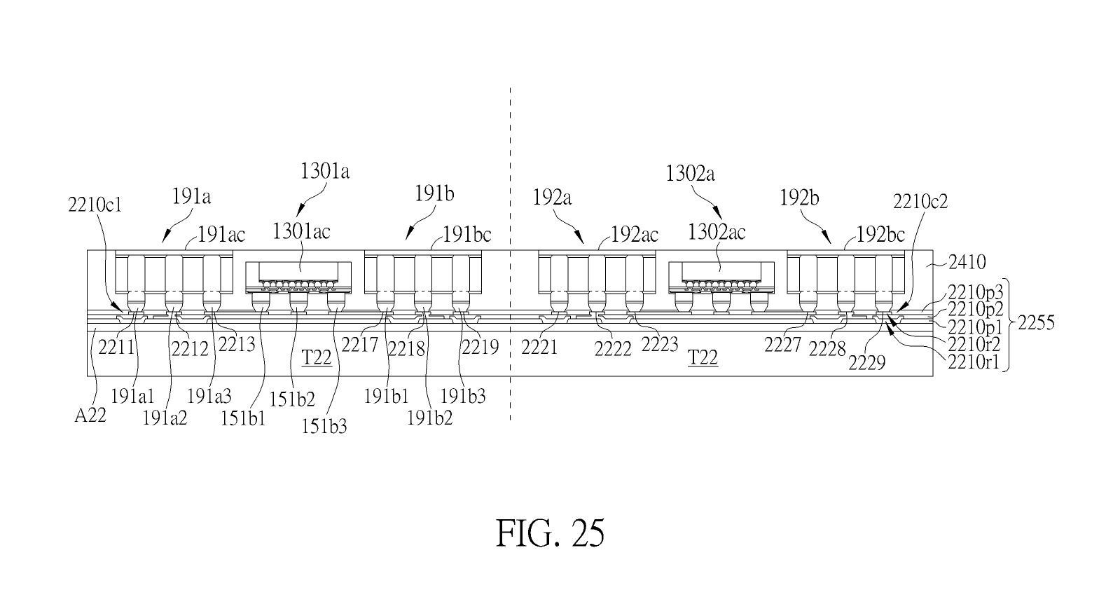

As shown in FIGS. 24-25, a polymer may be disposed on the redistribution layer 2255 to form an encapsulant 2410 to encapsulate the chip modules 1301a-1302a, the auxiliary conduction blocks 191a-191b and 192a-192b. Then, the encapsulant 2410 may be thinned to expose conductive layers 191ac, 191bc, 192ac and 192bc. The conductive layers 191ac, 191bc, 192ac and 192bc may each be a part of the auxiliary conduction blocks 191a-191b and 192a-192b respectively as shown in FIG. 25. The encapsulant 2410 may be thinned by grinding.

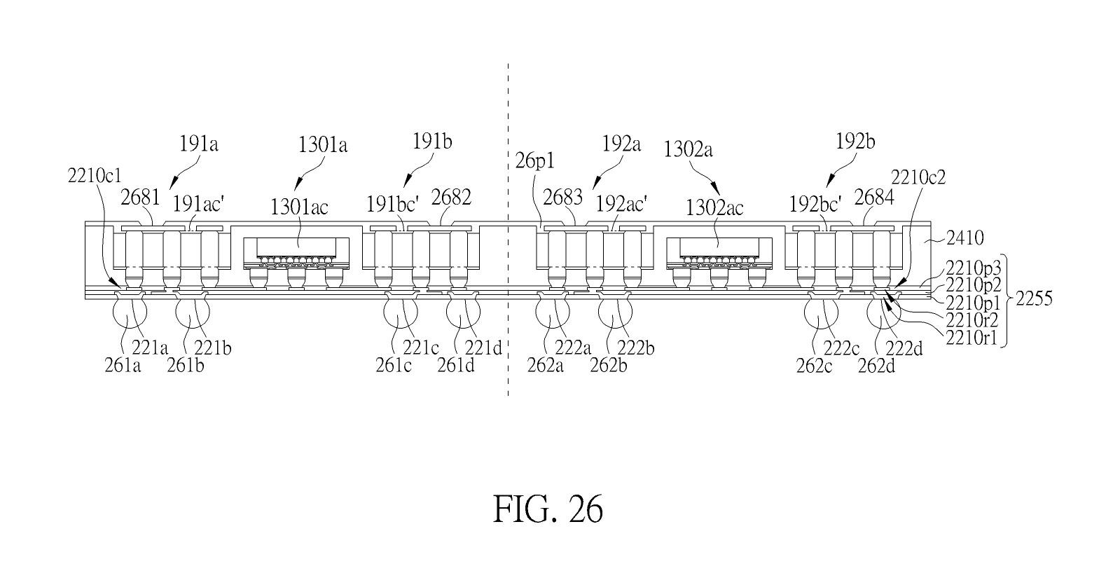

As shown in FIG. 26, the conductive layers 191ac, 191bc, 192ac and 192bc may be patterned by removing the undesired portions. A dielectric layer 26p1 may be formed on the thinned encapsulant 2410 and the conductive layers 191ac, 191bc, 192ac and 192bc. Then, the dielectric layer 26p1 may be patterned to expose a portion of each of the conductive layers 191ac, 191bc, 192ac and 192bc to form the interfaces 2681-2684. The tooling plate T22 and the release layer A22 may be removed by exposing the release layer A22 to light with a suitable wavelength, heating the release layer A22 or other means. A plurality of solder bumps 261a-261d and 262a-262d may be correspondingly disposed on the conductive interfaces 221a-221d and 222a-222d as shown in FIG. 26.

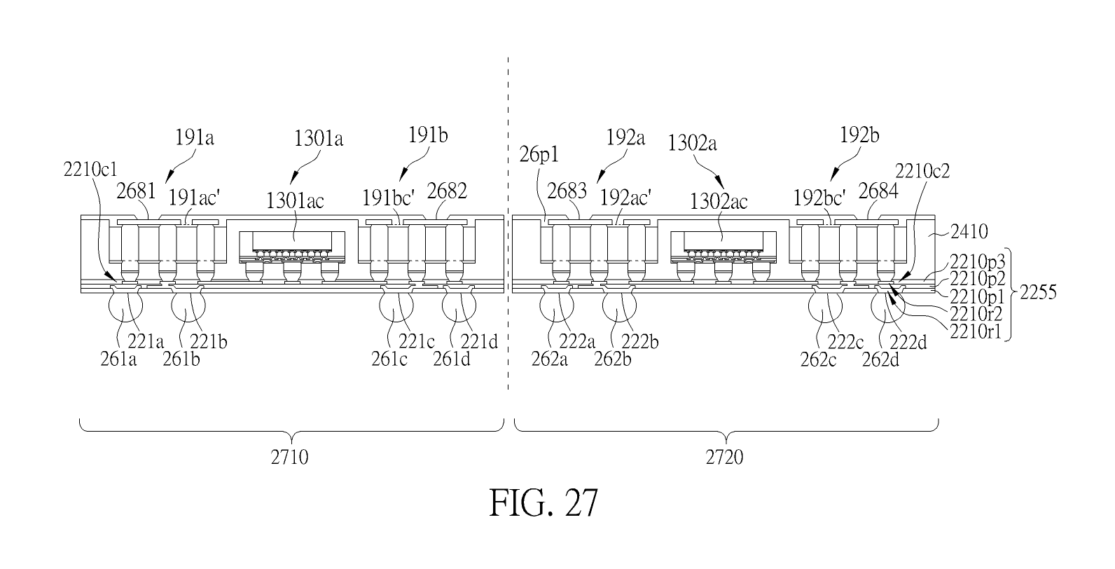

As shown in FIG. 27, the dielectric layer 26p1, then encapsulant 2410, and the redistribution layer 2255 may be cut to obtain a semiconductor package 2710 and another semiconductor package 2720. The semiconductor package 2710 may comprise the chip 1301ac. The semiconductor package 2720 may comprise the chip 1302ac. According to the process shown in FIGS. 22-27, a plurality of semiconductor packages may be formed. The number of semiconductor packages formed in FIGS. 22-27, may be exemplary rather than a limitation of the scope of the present invention. More semiconductor package may be formed according to the process. The process of the FIGS. 22-27 may be used to form a wafer based FiP (Fan-out in Package) structure.

Each of the packages 2710 and 2720 may include at least one fan-out chip in the package. This is the reason of that the packages 2710 and 2720 may be considered to have FiP (Fan-out in Package) structures. Each of the packages 2710 and 2720 may also have at least one vertical conduction block (e.g. the auxiliary conduction blocks 191a-191b and 192a-192b). The packages 2710 and 2720 may have FiP structure with a vertical package integration function (e.g. package-on-package (PoP)), and the FiP structure may be manufactured by wafer or panel Fan-out processes.

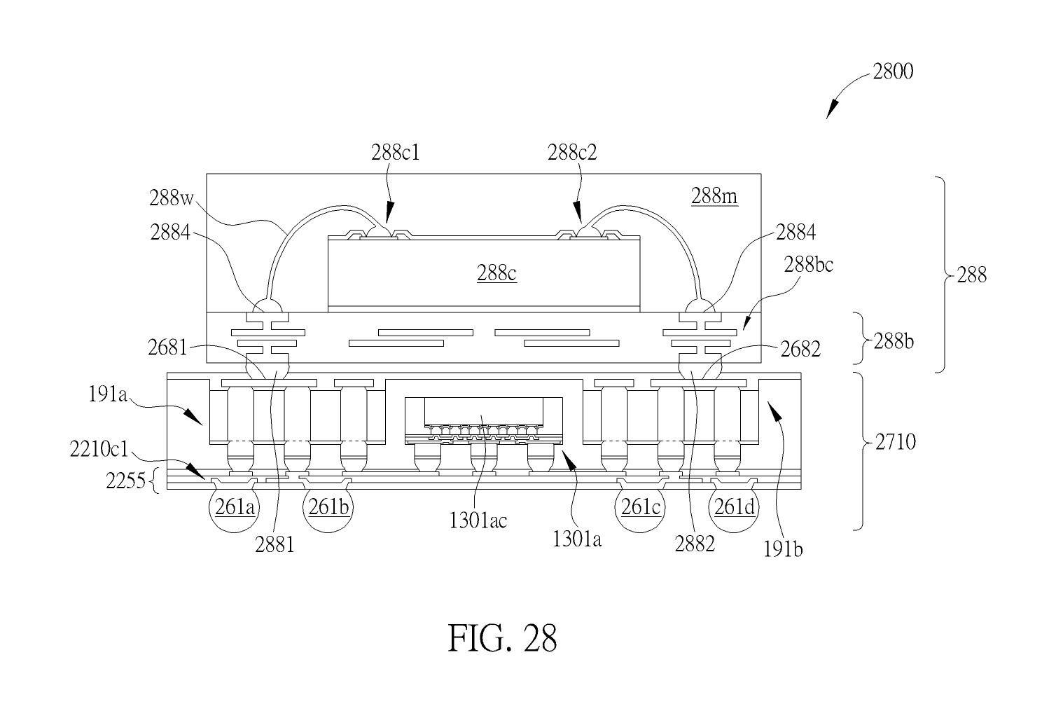

FIG. 28 illustrates a package structure 2800 according to an embodiment of the present invention. Since the structures and functions of the semiconductor packages 2710-2720 may be similar, the semiconductor package 2710 is used as an example to generate the package structure 2800. In FIG. 28, a chip module 288 may be assembled to the semiconductor package 2710 as described below. A substrate 288b of the chip module 288 may be disposed on the semiconductor package 2710 by connecting a set of input/output (I/O) interfaces 2881-2882 of the substrate 288b to the interfaces 2681-2682 of the semiconductor package 2710. The I/O interfaces 2881-2882 may be formed on the substrate 288b. A chip 288c may be disposed on the substrate 288b. A plurality of wires 288w may be bonded to a set of I/O interfaces 2884 and to a set of access ports 288c1-288c2 as shown in FIG. 28. A mold material may be filled to form a mold layer 288m to encapsulate the chip 288c and the wires 288w. The I/O interfaces 2881-2882 may be formed on a first side of the substrate 288b, and the I/O interfaces 2883-2884 may be formed on a second side of the substrate 288b. The I/O interfaces 2881-2882 may communicate with the I/O interfaces 2883-2884 via a circuit 288bc being of the substrate 288b and formed in the substrate 288b. As shown in FIG. 28, the chip 1301ac and the chip 288c may communicate with one another by using the semiconductor package 2710. A PoP (package on package) structure with wire-bonding may be carried out.

The bottom FiP structure (e.g. the semiconductor package 2710) may act as an bottom portion in a PoP application. Different types of top package may be compatible. For example, the top package may be a wire-bonded BGA, an FCCSP or an FCBGA (flip chip ball grid array).

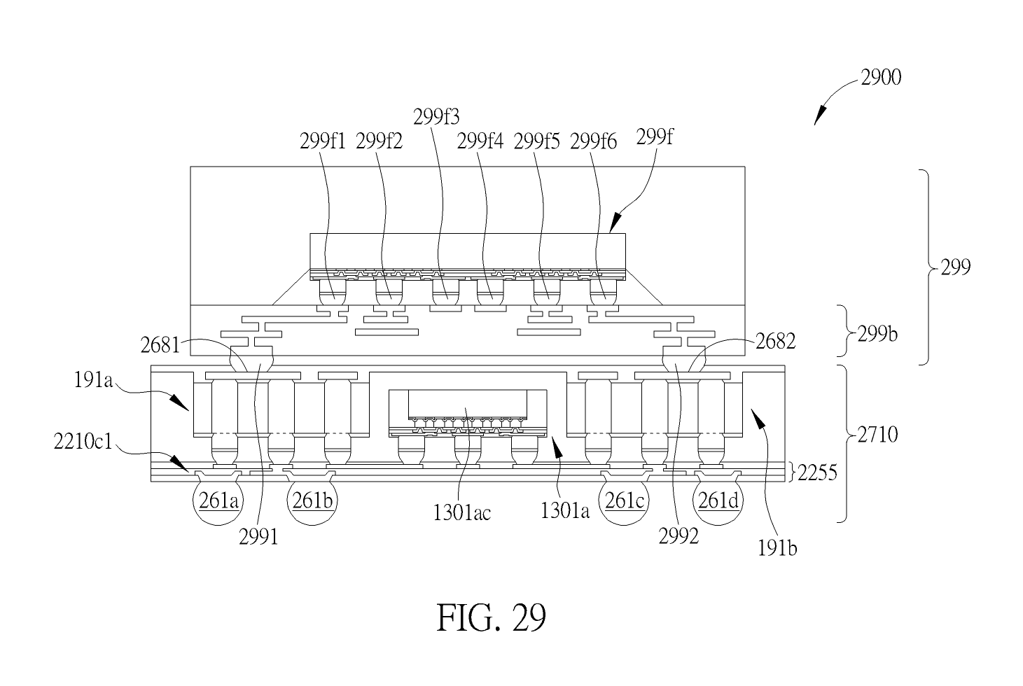

FIG. 29 illustrates a package structure 2900 according to an embodiment of the present invention. In the top package 299, the chip module 299f may be a chip with bumps used for a flip chip process. The bumps 299f1 to 299f6 may be used for flip chip application.

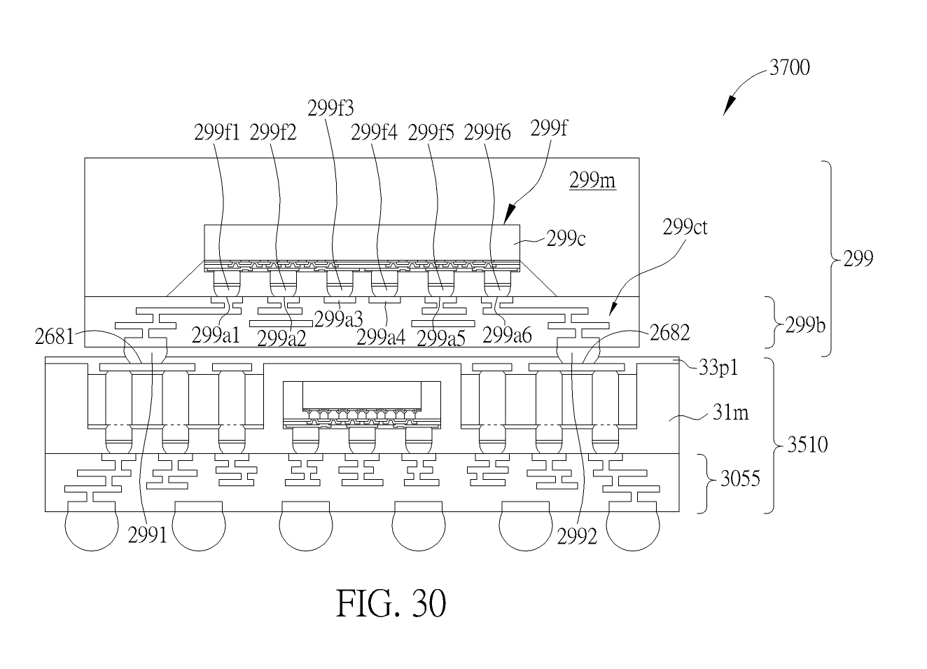

As shown in FIGS. 28-29, the redistribution layer 2255 may be formed between the solder bumps 261a-261d, and the auxiliary conduction blocks 191a-191b and the chip modules 1301a to provide the circuitries 2210c1. The chip modules 1301a may be a fan-out chip module having a fan-out structure. However, instead of forming the redistribution layer 2255 on the tooling plate T22 and the release layer A22 (as shown in FIGS. 23-25), the auxiliary conduction blocks 191a-191b and the fan-out chip module 1301a may be directly disposed on a substrate 3055 as shown in FIG. 30. FIG. 30 illustrates a package structure 3700 according to an embodiment of the present invention. The substrate 3055 may provide a similar function as the redistribution layer 2255. The substrate 3055 may have conductive interfaces on the two sides of the substrate 3055, and include a designable circuitry providing paths electrically connecting the conductive interfaces of the substrate 3055.

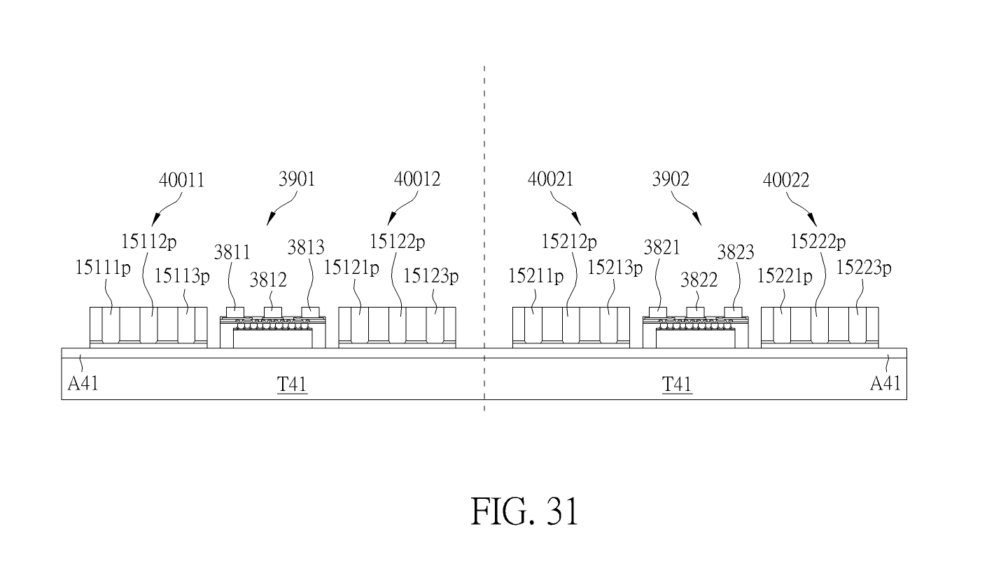

FIGS. 31-37 illustrate a process of generating a plurality of semiconductor packages 4710-4720 according to an embodiment of the present invention. In FIG. 31, the fan-out chip modules 3901-3902 may be formed with a similar process used to form the structure shown in FIG. 10 without disposing the conductive bumps 1011b-1013b and 1021b-1023b. The auxiliary conduction blocks 40011-40012 and 40021-40022 may be formed with a similar process used to form the structure shown in FIG. 17 without disposing the pillars (e.g. 1511ip-1513ip and 1521ip-1523ip shown in FIG. 19) and the bumps (e.g. 1511b-1513b and 1521b-1523b shown in FIG. 19 and 2511b-2513b and 2521b-2523b shown in FIG. 20).

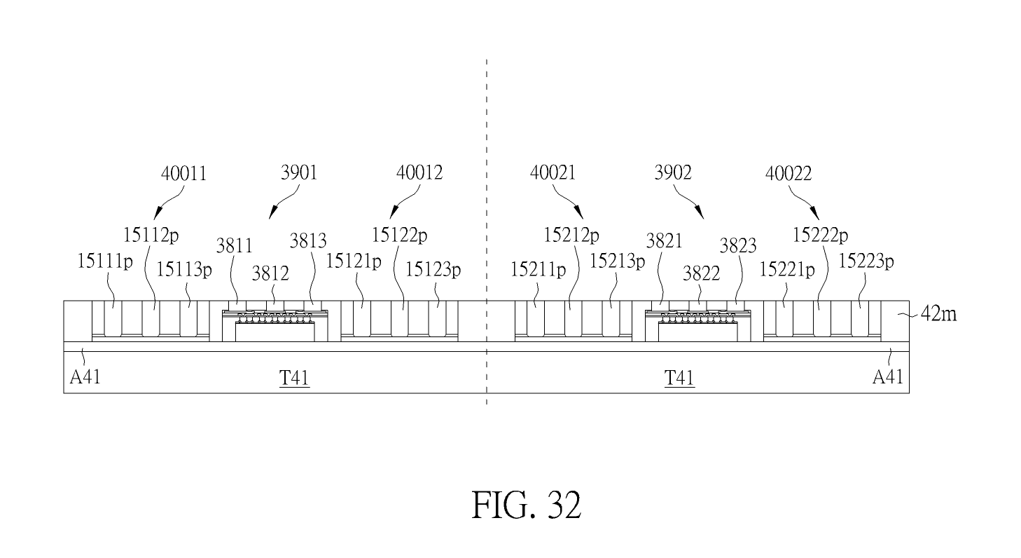

Since some process steps may be similar, FIGS. 31-37 merely show different processes that are not described above. As shown in FIG. 31, auxiliary conduction blocks 40011-40012 and 40021-40022 , and fan-out chip modules 3901-3902 may be disposed on a tooling plate T41 and an adhesive layer A41. In FIG. 31, the auxiliary conductive pillars 15111p-15113p, 15121p-15123p, 15211p-15213p and 15221p-15223p, and the conductive pillar bumps 3811-3813 and 3821-3823 may be set top. As shown in FIG. 32, a mold material may be filled to forma mold layer 42m, and the mold layer 42m may be thinned to expose the auxiliary conductive pillars 15111p-15113p, 15121p-15123p, 15211p-15213p and 15221p-15223p, and the conductive pillar bumps 3811-3813 and 3821-3823.

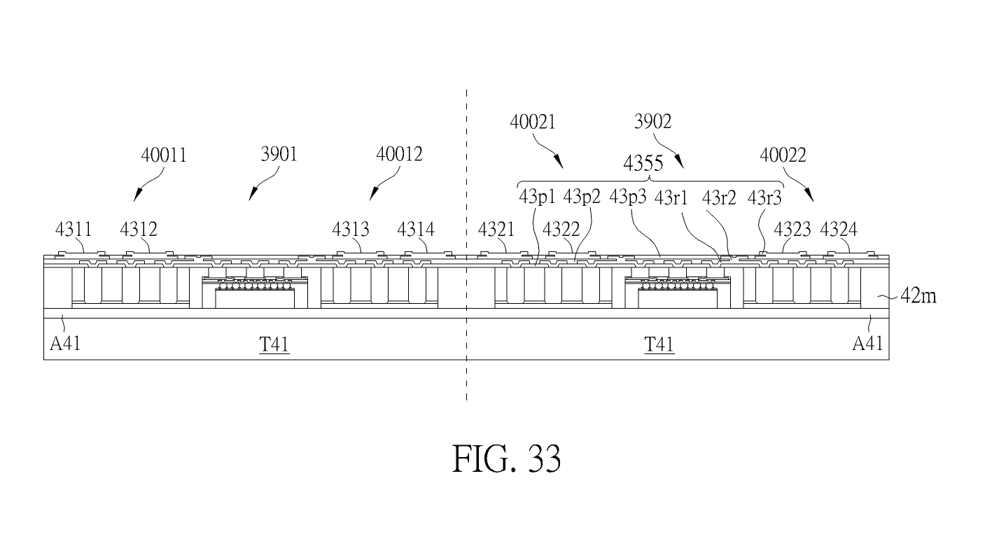

As shown in FIG. 33, a redistribution layer 4355 may be formed over the thinned mold layer 42m, the exposed auxiliary conductive pillars 15111p-15113p, 15121p-15123p, 15211p-15213p and 15221p-15223p, and the exposed conductive pillar bumps 3811-3813 and 3821-3823. The redistribution layer 4355 may include dielectric layers 43p1-43p3 and conductive layers 43r1-43r3. The dielectric layers 43p1-43p3 and conductive layers 43r1-43r3 may be formed and patterned to form a plurality of access interfaces 4311-4314 and 4321-4324, and a circuit used to connect the access interfaces 4311-4314 and 4321-4324 to the exposed auxiliary conductive pillars 15111p-15113p, 15121p-15123p, 15211p-15213p and 15221p-15223p, and the exposed conductive pillar bumps 3811-3813 and 3821-3823.

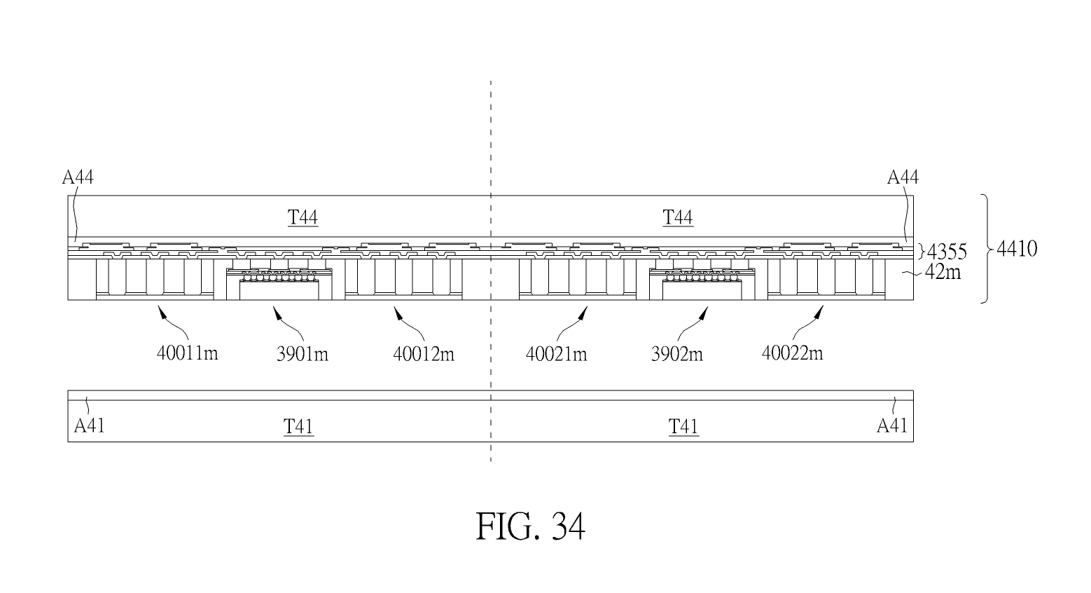

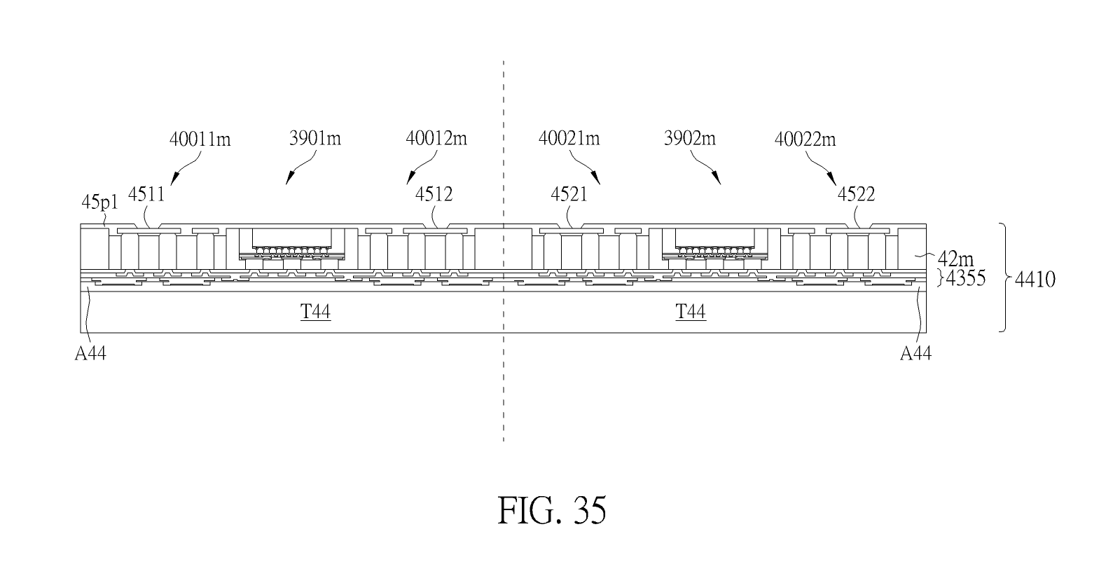

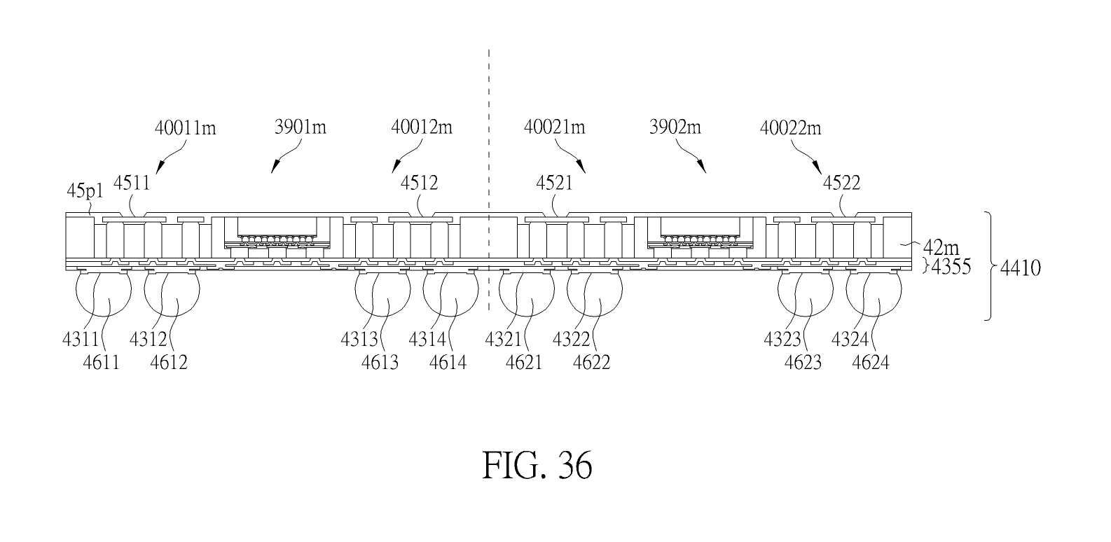

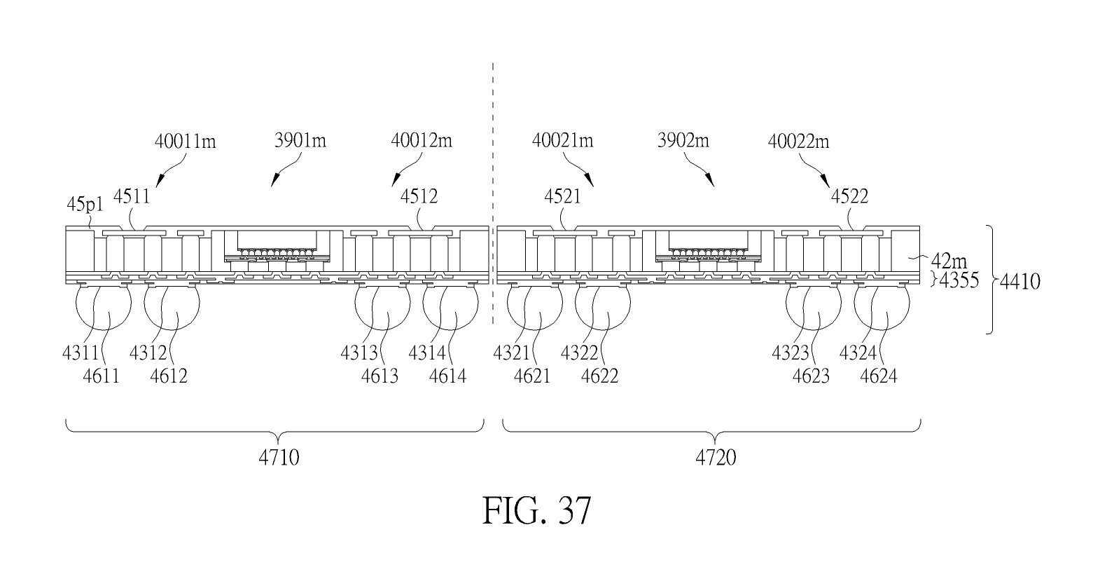

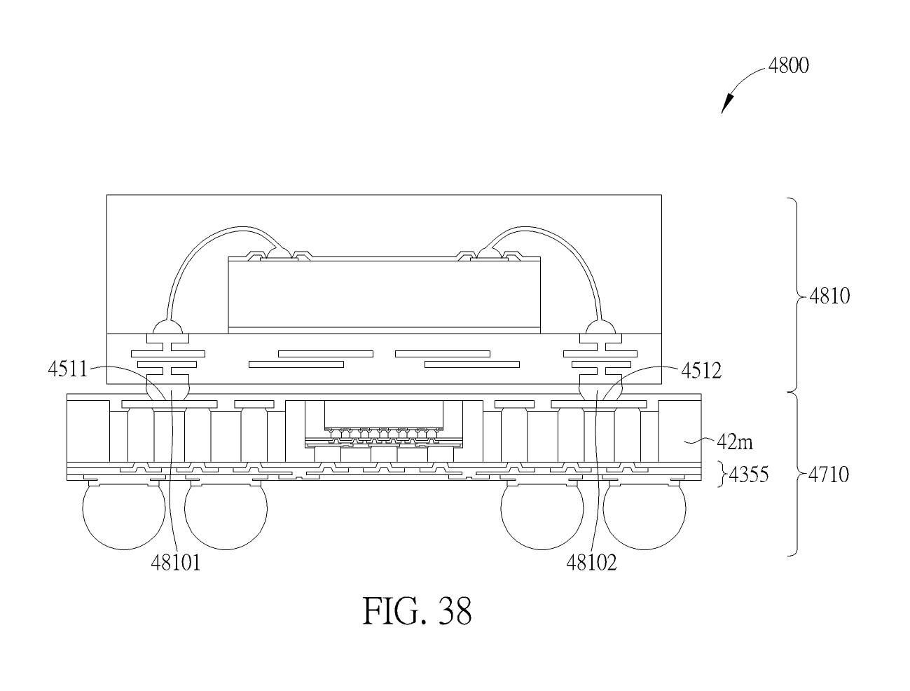

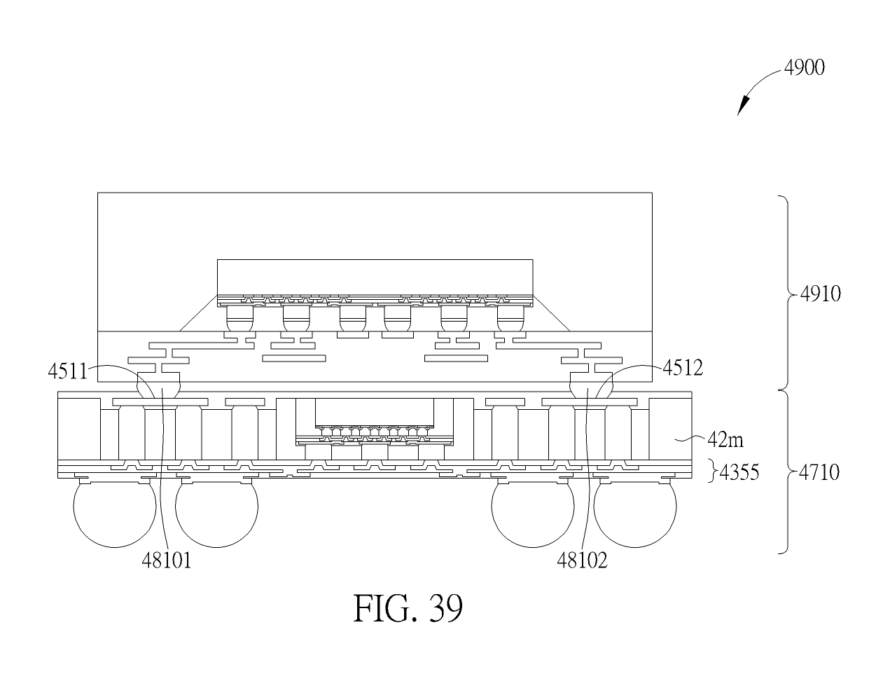

As shown in FIG. 34, the tooling plate T41 and the adhesive layer A41 may be removed, and an adhesive layer A44 and a tooling plate T44 may be disposed over the redistribution layer 4355. A structure 4410 may be obtained. Conductive layers 40011m, 40012m, 40021m and 40022m of the auxiliary conduction blocks 40011-40012 and 40021-40022 respectively may be exposed. As shown in FIG. 35, the structure 4410 in FIG. 34 may be flipped. At least one of the conductive layers 40011m, 40012m, 40021m and 40022m may be patterned. A dielectric layer 45p1 may be formed over the patterned conductive layers 40011m, 40012m, 40021m and 40022m. The dielectric layer 45p1 may be patterned to expose a portion of each of the conductive layers 40011m, 40012m, 40021m and 40022m to generate a plurality of interfaces 4511-4512 and 4521-4522. As shown in FIG. 36, the tooling plate T44 and the adhesive layer A44 may be removed. A plurality of solder bumps 4611-4614 and 4621-4624 may be disposed on the access interfaces 4311-4314 and 4321-4324 correspondingly. As shown in FIG. 37, the dielectric layers 45p1 and 42m, and the redistribution layer 4355 may be divided to obtain two semiconductor packages 4710-4720. Since the structures of the semiconductor packages 4710-4720 may be similar, the semiconductor packages 4710 may be used to described the package structures shown in FIGS. 38-39.

FIG. 38 illustrates a package structure 4800 according to an embodiment of the present invention. A chip module 4810 may be assembled to the semiconductor package 4710 by disposing a plurality of I/O interfaces 48101-48102 of the chip module 4810 on the interfaces 4511-4512. The chip module 4810 may be with a wire-bonding. FIG. 39 illustrates a package structure 4900 according to another embodiment of the present invention. In package structure 4900, a chip module 4910 may be assembled to the semiconductor package 4710 similarly. The chip module 4910 may include a flip-chip. According another embodiment, a set of passive components may be assembled to the semiconductor package 4710 according to applications.

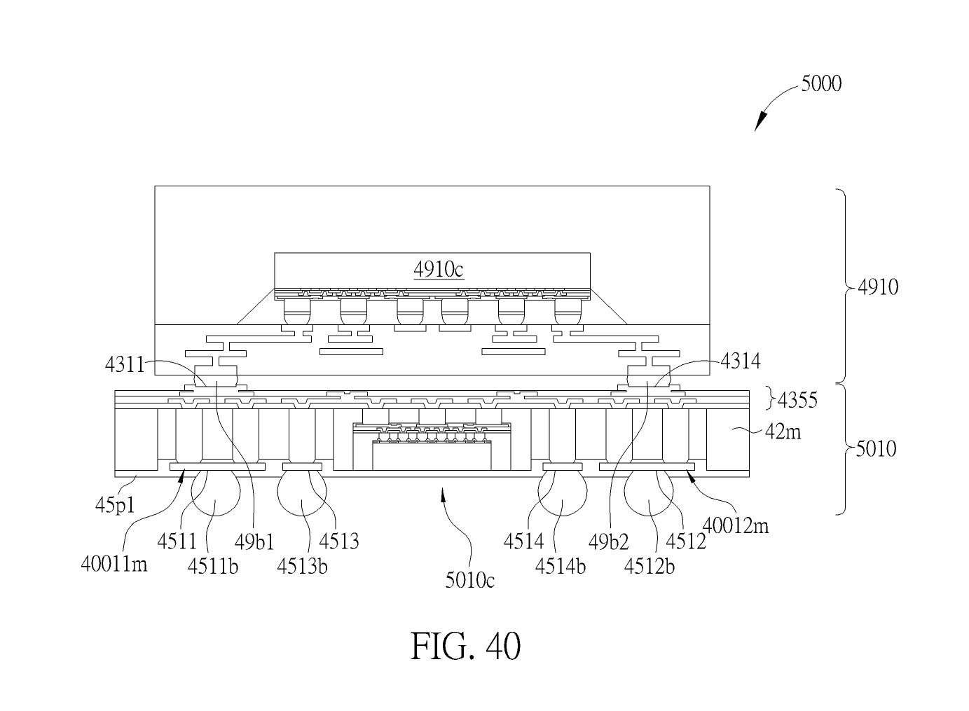

FIG. 40 illustrates a package structure 5000 according to an embodiment of the present invention. The package structure 5000 may be of a chip face-to-face (F2F) structure. In the package structure 5000, the chip module 4910 may be assembled to a semiconductor package 5010 by connecting interfaces 49b1-49b2 of the chip module 4910 to the access interfaces 4311 and 4314 of the semiconductor package 5010 correspondingly. The semiconductor package 5010 may be similar to a flipped semiconductor package 4710 of FIG. 37. However, the dielectric layer 45p1 may be patterned to expose different portions of the conductive layers 40011m-40022m to obtain interfaces 4511-4514. Solder bumps 4511b-4514b may be disposed on the interfaces 4511-4514. By using the package structure 5000, it may shorten electrical paths between the chip 4910c of the chip module 4910 and the chip 5010c of the semiconductor package 5010.

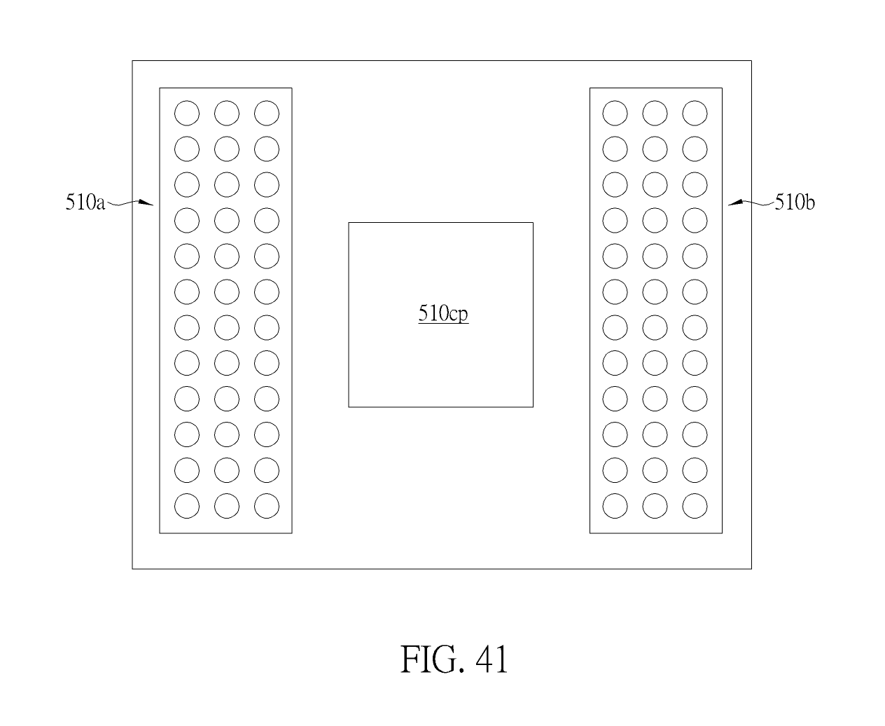

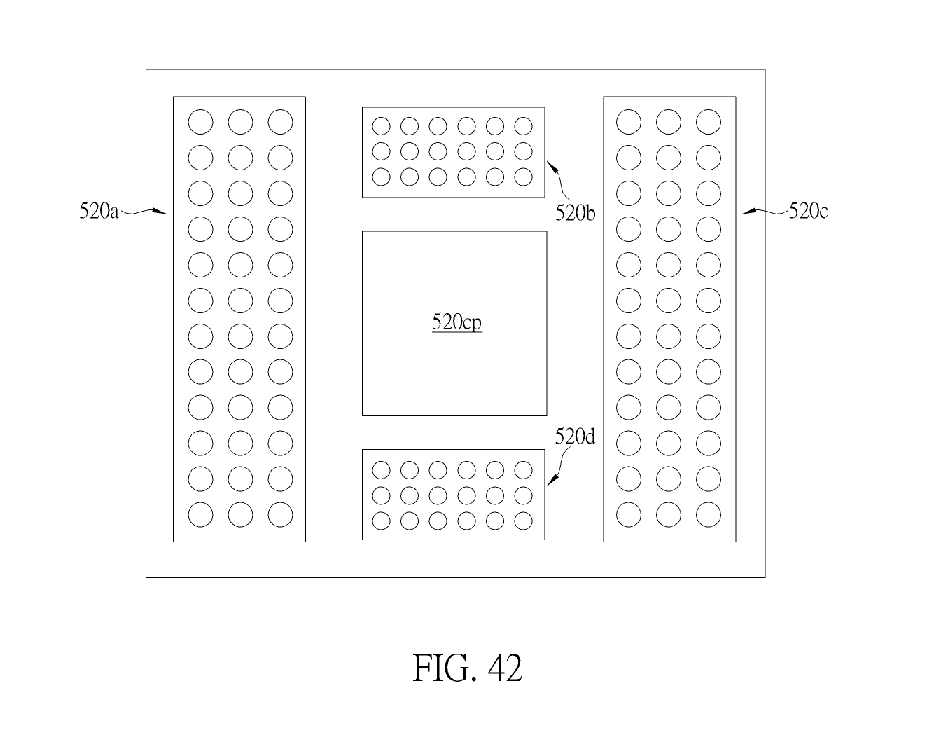

FIGS. 41-42 illustrate two top views of the layout of two chips and their corresponding auxiliary conduction blocks according to embodiments of the present invention. As shown in FIG. 41, two sets of auxiliary conduction blocks 510a-510b may be arranged at two sides of a chip 510cp. As shown in FIG. 42, four sets of auxiliary conduction blocks 520a-520d may be arranged at four sides of a chip 520cp. Each of the small circles may correspond to an auxiliary conductive pillar of an auxiliary conduction block. As shown in FIG. 42, in different auxiliary conduction blocks, the pitch, number and size of the auxiliary conductive pillars may be different. For example, the size, number and pitch of the auxiliary conductive pillars of the auxiliary conduction block 520b may be smaller than that of the auxiliary conduction block 520a.

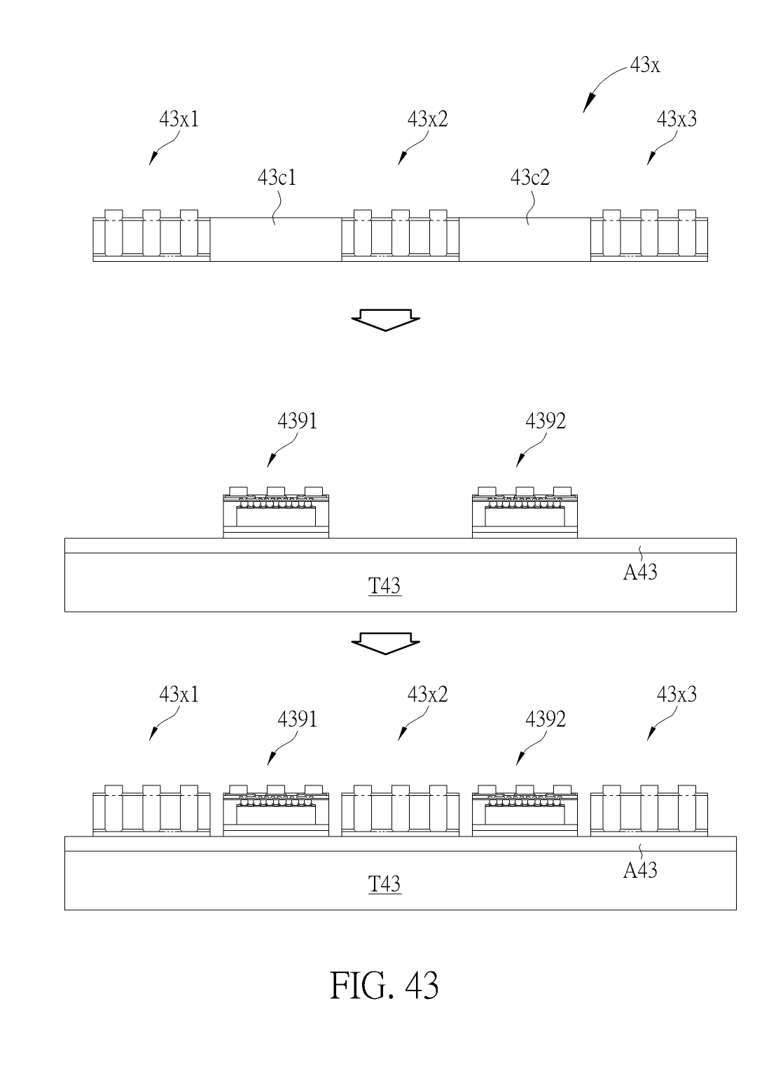

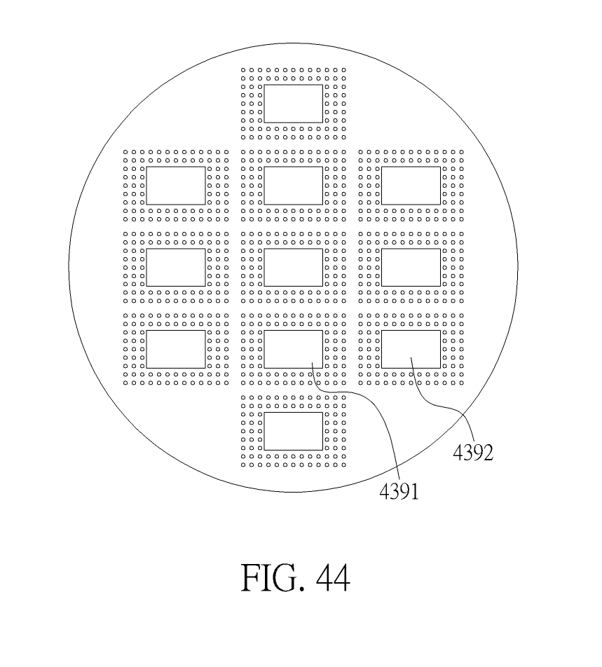

FIG. 43 illustrates a process of generating a package structure according to an embodiment of the present invention. FIG. 44 illustrates a top view of a structure formed after performing the process of FIG. 43. In FIG. 43, a plurality of auxiliary conduction blocks 43x1-43x3 may be formed on a block 43x. The block 43x may include a plurality of cavities 43c1-43c2. The block 43x may be disposed on the released layer A43 and the tooling plate T43 so that the chip units 4391-4392 may be positioned into the cavities 43c1-43c2. Multiple auxiliary conduction blocks (e.g. 43x1-43x3) and multiple chip units (e.g. 4391-4392) may be disposed on correct positions concurrently. In other words, the auxiliary conduction blocks and the chip units may be combined with one attaching step. The production throughput may be increased, and the production cost may be reduced. The pre-formed vertical conduction blocks (i.e. the foresaid auxiliary conduction blocks) may be of wafer base or panel base. The chip units may be disposed with the conductive bumps on top to make the active surface on top as a face up style. In FIG. 44, each of the little circles arranged in arrays may be top of an auxiliary conductive pillar of an auxiliary conduction block. The size and shape of the block 43x may be similar to those of the tooling plate T43 or a carrier such as a wafer. By means of the process of FIG. 43, efficiency may be further improved.

Since the number of auxiliary conduction blocks in a semiconductor package of an embodiment of the present invention may be flexibly arranged, and the conductive layer of auxiliary conduction block may be further designed and patterned, the design flexibility may be increased. By using a pre-generated auxiliary conduction block, the complexity of designing and manufacturing a package structure may be reduced. The auxiliary conduction block may be useful to support the package structure so as to avoid yield loss caused by high bump collapse. Since a plurality of chips may be stacked vertically, the area needed on a printed circuit board (PCB) may be saved. Applications of Multi-Chip Package (MCP) and/or System in Package (SiP) may be supported according to embodiments of the present invention. The process of the present invention may be used on a panel or a wafer. TSV interposer may be unnecessary due to the foresaid FiP structure. A FiP structure may convert small die pad pitch to be larger, and make the converted pad pitch to be compatible with a conventional IC substrate. The pre-formed vertical conduction blocks (i.e. the foresaid auxiliary conduction blocks) may be used for a PoP structure. The advantages of using the pre-formed conduction blocks may include that conductive pillars of variable sizes and pitches are easily compatible in one package. The packaging yield may be improved because some visual or electrical tests may be executed after the pre-formed conduction blocks are generated, and flawed conduction blocks may be picked out. Since good conduction blocks may be used for the subsequent packaging process, the yield may be increased. By using the auxiliary conduction block, cost and effort of manufacture may be reduced. Hence, by using process methods and structures of embodiments of the present invention, the problem of integrating multiple chips in a package can be well solved.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor package structure, comprising:
a chip module having a chip, the chip encapsulated by a first mold layer;
at least one auxiliary conduction block, each of the at least one auxiliary conduction block having a plurality of auxiliary conductive pillars and a second mold layer encapsulating the plurality of auxiliary conductive pillars;
an encapsulant encapsulating the first mold layer and the second mold layer; and
a redistribution layer disposed on the encapsulant, the redistribution layer being configured to electrically connect the chip of the chip module and the at least one auxiliary conduction block,
wherein the chip module, the at least one auxiliary conduction block, and the encapsulant are coplanar to each other.

2. The semiconductor package of claim 1, further comprising:
a plurality of conduction bumps correspondingly disposed on the chip module and the at least one auxiliary conduction block and configured to electrically connect the chip of the chip module and the at least one auxiliary conduction block to the redistribution layer.

3. The semiconductor package of claim 1, wherein
each of the at least one auxiliary conduction block further having a conductive layer disposed on the second mold layer, the conductive layer being patterned to form electrical connection among the plurality of auxiliary conductive pillars.

4. The semiconductor package of claim 1, wherein the at least one auxiliary conduction block has two or more auxiliary conduction blocks, each of the at least one auxiliary conduction block has a same number of auxiliary conductive pillars.

5. The semiconductor package of claim 1, wherein the at least one auxiliary conduction block has two or more auxiliary conduction blocks, each of the at least one auxiliary conduction block has a different number of auxiliary conductive pillars.

6. The semiconductor package of claim 1, wherein the chip module further comprises:
a plurality of conductive pillar bumps correspondingly disposed on a plurality of conductive interfaces of the chip, the first mold layer encapsulating the plurality of conductive pillar bumps and the chip;
a redistribution layer formed on the first mold layer of the chip module and electrically connected to the plurality of conductive pillar bumps; and
a plurality of intermediary conductive pillars electrically connected to the plurality of conductive pillar bumps through the redistribution layer of the chip module.

7. The semiconductor package of claim 6, wherein the chip is electrically connected to the redistribution layer of the semiconductor package through the plurality of conductive pillar bumps.

8. The semiconductor package of claim 1, further comprising:
a plurality of solder bumps disposed on and electrically connected to the redistribution layer of the semiconductor package.

9. The semiconductor package of claim 1, further comprising:
a dielectric layer formed on a surface of the encapsulant opposite the redistribution layer of the semiconductor package, the dielectric layer having recessed areas formed to expose portions of the at least one auxiliary conduction block.

10. (canceled)

11. A method of forming a semiconductor package, comprising:
providing a tooling plate;
disposing a chip module on the tooling plate, the chip module having a chip_encapsulated by a first mold layer;
disposing at least one auxiliary conduction block on the tooling plate, each of the at least one auxiliary conduction block having a plurality of auxiliary conductive pillars and a second mold layer encapsulating the plurality of auxiliary conductive pillars;
forming an encapsulant on the tooling plate to encapsulate the chip module and the at least one auxiliary conduction block;
forming a redistribution layer on the tooling plate, the redistribution layer being configured to electrically connect the chip of the chip module and the at least one auxiliary conduction block; and
removing the tooling plate
wherein the chip module, the at least one auxiliary conduction block, and the encapsulant are coplanar to each other.

12. The method of claim 11, wherein forming the chip module disposed on the tooling plate comprises:
forming a plurality of conductive pillar bumps correspondingly on a plurality of conductive interfaces of the chip;
encapsulating the plurality of conductive pillar bumps and the chip using the first mold layer;
forming a redistribution layer on the first mold layer, the redistribution layer being electrically connected to the plurality of conductive pillar bumps; and
forming a plurality of intermediary conductive pillars electrically connected to the plurality of conductive pillar bumps through the redistribution layer of the chip module.

13. The method of claim 12, wherein the chip is electrically connected to the redistribution layer of the semiconductor package through the plurality of conductive pillar bumps.

14. The method of claim 11, wherein forming the at least one auxiliary conduction block disposed on the tooling plate comprises:
providing a carrier;
forming a conductive layer on the carrier;
forming a dielectric layer on the conductive layer;
patterning the dielectric layer to form a plurality of openings;
forming a plurality of auxiliary conductive pillars on the conductive layer via the openings correspondingly; and
forming the second mold layer to encapsulate the plurality of auxiliary conductive pillars; and
thinning the mold layer to expose the plurality of auxiliary conductive pillars.

15. The method of claim 11, wherein the chip module, the at least one auxiliary conduction block, and the encapsulant are coplanar to each other.

16. The method of claim 11, further comprising:
disposing a plurality of conduction bumps on the chip module and the at least one auxiliary conduction block correspondingly for electrically connecting to the chip of the chip module and the at least one auxiliary conduction block to the redistribution layer.

17. The method of claim 11, wherein disposing the at least one auxiliary conduction block comprises:
disposing two or more auxiliary conduction blocks, wherein each of the at least one auxiliary conduction block has a same number of auxiliary conductive pillars.

18. The method of claim 11, wherein disposing the at least one auxiliary conduction block comprises:
disposing two or more auxiliary conduction blocks, wherein each of the at least one auxiliary conduction block has a different number of auxiliary conductive pillars.

19. The method of claim 11, further comprising:
disposing a plurality of solder bumps on and electrically connected to the redistribution layer of the semiconductor package.

20. The method of claim 11, further comprising:
forming a dielectric layer on a surface of the encapsulant opposite the redistribution layer of the semiconductor package, the dielectric layer having recessed areas formed to expose portions of the at least one auxiliary conduction block.
